(19) United States
(12) Patent Application Publication
(10) Pub. No.: US 2021/0234038 A1
(43) Pub. Date: Jul. 29, 2021

(54) SEMICONDUCTOR DEVICE

(71) Applicant: PANASONIC INTELLECTUAL PROPERTY MANAGEMENT CO., LTD., Osaka (JP)

(72) Inventors: Masao UCHIDA, Osaka (JP); Kouichi SAITOU, Toyama (JP); Takashi HASEGAWA, Toyama (JP); Takayuki WAKAYAMA, Toyama (JP)

(21) Appl. No.: 17/155,782

(22) Filed: Jan. 22, 2021

(30) Foreign Application Priority Data
Jan. 23, 2020 (JP) 2020-009029

(51) Int. Cl. H01L 29/78; H01L 29/16; H01L 29/06

(52) U.S. Cl. CPC H01L 29/7811; H01L 29/0619; H01L 29/1608

(57) ABSTRACT

A semiconductor device includes: a silicon carbide semiconductor layer of a first conductivity type disposed on a semiconductor substrate; a first impurity region of a second conductivity type located on a surface of the semiconductor layer, the first impurity region surrounding the active region; a plurality of rings of the second conductivity type surrounding the first impurity region; a first insulating film disposed to cover a portion of the first impurity region and the plurality of rings, the first insulating film having a first aperture; a first electrode within the first aperture, the first electrode; a second insulating film disposed to surround the active region, the second insulating film having a higher moisture resistance than the first insulating film; a third insulating film covering a portion of the first electrode and the second insulating film, and a second electrode disposed on the rear face of the semiconductor substrate.

### BACKGROUND

### 1. Technical Field

The present disclosure relates to a semiconductor device.

### 2. Description of the Related Art

Silicon carbide (SiC) is a semiconductor material which has a larger band gap and a higher hardness than those of silicon (Si). SiC has been applied to semiconductor devices such as switching elements and rectifier elements, for example. As compared to a semiconductor device which is based on Si, a semiconductor device which is based on SiC has an advantage of reduced power loss, for example.

Representative semiconductor devices which are based on SiC are metal-insulator-semiconductor field-effect transistors (MISFET) and Schottky-barrier diodes (SBD). Metal-oxide-semiconductor field-effect transistors (MOSFET) are a kind of MISFET. Junction-barrier Schottky diodes (JBS) are a kind of SBD.

A semiconductor device which is based on SiC (hereinafter simply referred to as a “semiconductor device”) includes a semiconductor substrate and a semiconductor layer of SiC that is disposed on a principal face of the semiconductor substrate. Above the semiconductor layer, electrodes to be electrically connected to the outside of the device are disposed as front face electrodes. At the end or in the periphery of the semiconductor device, a termination structure for mitigating electric fields is provided. Moreover, when the semiconductor device is packaged or made into a module, a passivation film covering the termination structure is provided in order to suppress structural destruction due to interferences from a resin that covers the semiconductor device. The passivation film may be an organic protective film such as polyimide, for example.

With an aim to further enhance reliability of a semiconductor device, a structure has been proposed in which a termination structure of a semiconductor device is covered with a silicon nitride (SiN) film, with an organic protective film provided thereon (see Patent Document 1).

Patent Document 1: Japanese Laid-Open Patent Publication No. 2019-175937

### SUMMARY

According to one aspect of the present disclosure, there is provided a semiconductor device having a high breakdown voltage and a high reliability.

In order to solve the above problem, a semiconductor device according to one aspect of the present disclosure comprises: a semiconductor substrate including an active region and a termination region that surrounds the active region, the semiconductor substrate having a principal face and a rear face; a silicon carbide semiconductor layer of a first conductivity type disposed on the principal face of the semiconductor substrate; a first impurity region of a second conductivity type located on a surface of the semiconductor layer within the termination region, the first impurity region surrounding the active region when viewed from a normal direction of the principal face of the semiconductor substrate; a plurality of rings of the second conductivity type located on the surface of the semiconductor layer within the termination region, the plurality of rings being spaced apart from the first impurity region and surrounding the first impurity region when viewed from the normal direction of the principal face of the semiconductor substrate; a first insulating film disposed on the semiconductor layer so as to cover a portion of the first impurity region and the plurality of rings, the first insulating film having a first aperture above a portion of the first impurity region; a first electrode disposed on the first insulating film and within the first aperture, the first electrode being electrically connected to the first impurity region; a second insulating film disposed on the first insulating film within the termination region so as to surround the active region, the second insulating film having a higher moisture resistance than that of the first insulating film; a third insulating film being located above the first insulating film and covering a portion of the first electrode and the second insulating film within the active region and the termination region, the third insulating film being an organic insulating film; and a second electrode disposed on the rear face of the semiconductor substrate, wherein, the second insulating film has a first face that is in contact with the first insulating film, and, when viewed from the normal direction of the principal face of the semiconductor substrate, the first face surrounds the active region, an inner peripheral edge of the first face is located inward of an outer peripheral edge of the first impurity region, and an outer peripheral edge of the first face is located between a first ring and a second ring among the plurality of rings, the first ring being located innermost and the second ring being located outermost among the plurality of rings; and the second insulating film is not in contact with an upper face of the first electrode.

According to one aspect of the present disclosure, there is provided a semiconductor device having a high breakdown voltage and a high reliability.

### BRIEF DESCRIPTION OF THE DRAWINGS

FIG. 1 is a diagram showing an upper face of a semiconductor device according to an embodiment of the present disclosure.

FIG. 2 is a diagram showing a cross section of a semiconductor device according to an embodiment of the present disclosure.

FIG. 3 is a diagram showing an upper face of an SBD (JBS structure) according to an embodiment of the present disclosure.

FIG. 4 is a diagram showing a cross section of an SBD (JBS structure) according to an embodiment of the present disclosure.

FIG. 5 is a diagram showing a cross section of a semiconductor device according to Comparative Example.

FIG. 6 is a diagram showing a cross section of another example SBD (JBS structure) according to an embodiment of the present disclosure.

FIG. 7 is a diagram showing a cross section of still another example SBD (JBS structure) according to an embodiment of the present disclosure.

FIG. 8 is a step-by-step cross-sectional view showing a method of producing an SBD (JBS structure) according to an embodiment of the present disclosure.

FIG. 9 is a step-by-step cross-sectional view showing a method of producing an SBD (JBS structure) according to an embodiment of the present disclosure.

FIG. 10 is a step-by-step cross-sectional view showing a method of producing an SBD (JBS structure) according to an embodiment of the present disclosure.

FIG. 11 is a step-by-step cross-sectional view showing a method of producing an SBD (JBS structure) according to an embodiment of the present disclosure.

FIG. 12 is a step-by-step cross-sectional view showing a method of producing an SBD (JBS structure) according to an embodiment of the present disclosure.

FIG. 13 is a step-by-step cross-sectional view showing a method of producing an SBD (JBS structure) according to an embodiment of the present disclosure.

FIG. 14 is a step-by-step cross-sectional view showing a method of producing an SBD (JBS structure) according to an embodiment of the present disclosure.

FIG. 15 is a step-by-step cross-sectional view showing a method of producing an SBD (JBS structure) according to an embodiment of the present disclosure.

FIG. 16 is a step-by-step cross-sectional view showing a method of producing an SBD (JBS structure) according to an embodiment of the present disclosure.

FIG. 17A is a diagram showing characteristic fluctuations of a semiconductor device according to an embodiment of the present disclosure after an HTRB test.

FIG. 17B is a diagram showing characteristic fluctuations of a semiconductor device according to an embodiment of the present disclosure after an HTRB test.

FIG. 17C is a diagram showing characteristic fluctuations of a semiconductor device according to an embodiment of the present disclosure after an HTRB test.

FIG. 18A is a diagram showing characteristic fluctuations of a semiconductor device according to an embodiment of the present disclosure after a THB test.

FIG. 18B is a diagram showing characteristic fluctuations of a semiconductor device according to an embodiment of the present disclosure after a THB test.

FIG. 18C is a diagram showing characteristic fluctuations of a semiconductor device according to an embodiment of the present disclosure after a THB test.

FIG. 19 is a diagram showing an upper face of a MISFET according to an embodiment of the present disclosure.

FIG. 20 is a diagram showing an upper face of a MISFET according to an embodiment of the present disclosure.

FIG. 21 is a diagram showing a cross section of a MISFET according to an embodiment of the present disclosure.

FIG. 22 is a diagram showing a cross section of a MISFET according to an embodiment of the present disclosure.

FIG. 23 is a diagram showing a cross section of another example of a MISFET according to an embodiment of the present disclosure.

FIG. 24 is a diagram showing a cross section of still another example of a MISFET according to an embodiment of the present disclosure.

FIG. 25A is a diagram showing a cross section of a second insulating film according to an embodiment of the present disclosure.

FIG. 25B is a diagram showing a cross section of a second insulating film according to an embodiment of the present disclosure.

FIG. 25C is a diagram showing a cross section of a second insulating film according to an embodiment of the present disclosure.

### DETAILED DESCRIPTION

A highly-reliable semiconductor device which can withstand use in a high-temperature, high-humidity, and/or high-breakdown voltage environment is desired.

However, according to studies by the inventors, it has been found that conventional device structures proposed in Patent Document 1 and the like may cause deteriorations in the device characteristics through operation in a high-temperature or high-humidity environment, such that sufficient reliability may not be provided. Details thereof will be described later.

The inventors have arrived at semiconductor devices according to aspects as follows.

A semiconductor device according to one aspect of the present disclosure comprises: a semiconductor substrate including an active region and a termination region that surrounds the active region, the semiconductor substrate having a principal face and a rear face; a silicon carbide semiconductor layer of a first conductivity type disposed on the principal face of the semiconductor substrate; a first impurity region of a second conductivity type located on a surface of the semiconductor layer within the termination region, the first impurity region surrounding the active region when viewed from a normal direction of the principal face of the semiconductor substrate; a plurality of rings of the second conductivity type located on the surface of the semiconductor layer within the termination region, the plurality of rings being spaced apart from the first impurity region and surrounding the first impurity region when viewed from the normal direction of the principal face of the semiconductor substrate; a first insulating film disposed on the semiconductor layer so as to cover a portion of the first impurity region and the plurality of rings, the first insulating film having a first aperture above a portion of the first impurity region; a first electrode disposed on the first insulating film and within the first aperture, the first electrode being electrically connected to the first impurity region; a second insulating film disposed on the first insulating film within the termination region so as to surround the active region, the second insulating film having a higher moisture resistance than that of the first insulating film; a third insulating film being located above the first insulating film and covering a portion of the first electrode and the second insulating film within the active region and the termination region, the third insulating film being an organic insulating film; and a second electrode disposed on the rear face of the semiconductor substrate, wherein, the second insulating film has a first face that is in contact with the first insulating film, and, when viewed from the normal direction of the principal face of the semiconductor substrate, the first face surrounds the active region, an inner peripheral edge of the first face is located inward of an outer peripheral edge of the first impurity region, and an outer peripheral edge of the first face is located between a first ring and a second ring among the plurality of rings, the first ring being located innermost and the second ring being located outermost among the plurality of rings; and the second insulating film is not in contact with an upper face of the first electrode.

The second insulating film may comprise e.g. silicon nitride.

When viewed from the normal direction of the principal face of the semiconductor substrate, an outer peripheral edge of the third insulating film may be located outward of the outer peripheral edge of the first face of the second insulating film; and in a plane parallel to the principal face of the semiconductor substrate, a minimum distance L between the outer peripheral edge of the first face of the second insulating film and the outer peripheral edge of the third insulating film may satisfy L≥65 μm.

The second insulating film may not be in contact with the first electrode.

The first insulating film may be a silicon oxide film.

The first insulating film may have a second aperture through which a portion of the semiconductor layer is exposed, and, when viewed from the normal direction of the principal face of the semiconductor substrate, the second aperture may be located outward of the plurality of rings, the semiconductor device further comprising a seal ring disposed on the first insulating film and within the second aperture.

The third insulating film may cover the seal ring.

The first electrode may have has a multilayer structure, the multilayer structure including as a lowermost layer a metal layer that is in contact with the semiconductor layer, the metal layer forming a Schottky junction with the semiconductor layer.

Within the active region, the semiconductor device may include e.g. a plurality of barrier regions of the second conductivity type that are located on the surface of the semiconductor layer.

The semiconductor device may further comprise e.g. a plurality of unit cells disposed in the active region, each of the plurality of unit cells comprising: a body region of the second conductivity type selectively formed on the surface of the semiconductor layer; a source region of the first conductivity type located on a surface of the body region and being disposed at a distance from an outer peripheral edge of the body region; a contact region of the second conductivity type selectively formed on the surface of the semiconductor layer, the contact region containing an impurity of the second conductivity type at a higher concentration than that in the body region, the contact region adjoining the source region and being connected to the body region; a gate insulating film disposed on the semiconductor layer; a gate electrode being located on the gate insulating film and covering a portion of the body region via the gate insulating film; and a source electrode forming ohmic junctions with the source region and the contact region; the first insulating film covers an upper face and a side face of the gate electrode; and the first electrode is electrically connected with the source electrode.

Hereinafter, more specific embodiments of the present disclosure will be described. Note however that unnecessarily detailed descriptions may be omitted. For example, detailed descriptions on what is well known in the art or redundant descriptions on what is substantially the same construction may be omitted. This is to avoid lengthy description, and facilitate the understanding of those skilled in the art. The accompanying drawings and the following description, which are provided by the present inventors so that those skilled in the art can sufficiently understand the present disclosure, are not intended to limit the scope of claims. In the following description, identical or similar constituent elements are denoted by identical reference numerals.

### Embodiment

Hereinafter, with reference to the drawings, an embodiment of a semiconductor device according to the present disclosure will be described. Although the present embodiment illustrates a case where the first conductivity type is the n type and the second conductivity type is the p type, this is not a limitation. In embodiments of the present disclosure, the first conductivity type may be the p type and the second conductivity type may be the n type.

(Structure of Semiconductor Device)

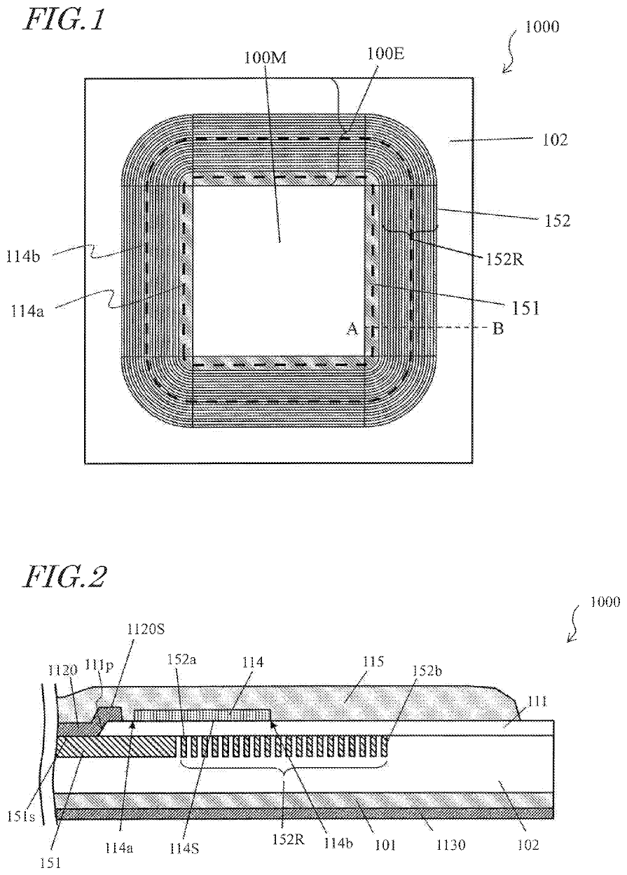

FIG. 1 and FIG. 2 are a plan view and a cross-sectional view, respectively, for schematically describing a semiconductor device 1000 according to the present embodiment.

The semiconductor device 1000 includes: an active region (also referred to as a primary conducting region or an effective region) 100M; and a termination region 100E disposed around the active region 100M so as to surround the active region 100M.

FIG. 1 shows the following elements of the semiconductor device 1000: a semiconductor layer (drift layer) 102 of a first conductivity type; a first impurity region 151 of a second conductivity type; and a plurality of rings 152 of the second conductivity type. Within the termination region 100E, the first impurity region 151 and the plurality of rings 152 are formed on the surface of the semiconductor layer 102. When viewed from the normal direction of a principal face of the semiconductor substrate 101, the first impurity region 151 surrounds the active region 100M. When viewed from the normal direction of the principal face of the semiconductor substrate 101, the plurality of rings 152 of the second conductivity type are disposed outside the first impurity region 151, so as to be spaced apart from the first impurity region 151. In the present specification, the structure including the plurality of rings 152 will be referred to as an FLR (Field Limiting Ring) structure 152R.

FIG. 2 shows a cross-sectional structure of the termination region 100E of the semiconductor device 1000, as taken along line A-B in FIG. 1. As shown in FIG. 2, the semiconductor device 1000 includes: the semiconductor substrate 101; the semiconductor layer 102 disposed on the principal face of the semiconductor substrate 101; a first electrode 1120; a first insulating film 111; a second insulating film 114; and a third insulating film 115. The semiconductor substrate 101 is, for example, a silicon carbide substrate of the first conductivity type. The semiconductor layer 102 is a silicon carbide semiconductor layer of the first conductivity type. The semiconductor device 1000 may include a buffer layer between the semiconductor layer 102 and the semiconductor substrate 101. The buffer layer is a silicon carbide layer of the first conductivity type. The buffer layer may be omitted.

As described earlier, the surface of the semiconductor layer 102 includes: the first impurity region 151 of the second conductivity type; and the plurality of rings 152 of the second conductivity type surrounding the first impurity region 151 at its periphery. The number of rings 152 in the FLR structure 152R is not limited to the example shown in the figures. In the plan view of FIG. 1, the number of rings 152 is shown reduced for ease of understanding.

The first insulating film 111 is disposed on a portion of the semiconductor layer 102. The first insulating film 111 is a silicon oxide (SiO₂) film, for example. The first insulating film 111 covers a portion of the first impurity region 151, and covers the FLR structure 152R including the plurality of rings 152. The first insulating film 111 has a first aperture 111p on an upper face of the first impurity region 151. Herein, the first aperture 111p exposes a portion 151s of the first impurity region 151.

The first electrode 1120 is disposed on the semiconductor layer 102. The first electrode 1120 is disposed in the first aperture 111p of the first insulating film 111, so as to be electrically connected to the first impurity region 151 within the first aperture 111p. The first electrode 1120 may be directly in contact with the portion 151s of the first impurity region 151, within the first aperture 111p. The first electrode 1120 may cover a portion of the upper face of the first insulating film 111 and side walls of the first aperture 111p of the first insulating film 111.

The second insulating film 114 is disposed so as to cover at least a portion of the first insulating film 111. When viewed from the normal direction of the principal face of the semiconductor substrate 101, the second insulating film 114 may be disposed so as to surround the active region 100M. A lower end (lower face) of the second insulating film 114 is in contact with the first insulating film 111. The second insulating film 114 is not in contact with an upper face 1120S of the first electrode 1120. As shown in the figure, the second insulating film 114 may be disposed at an interval from the first electrode 1120.

The second insulating film 114 has a higher moisture resistance than that of the first insulating film 111. As used herein, having a “high moisture resistance” refers to unlikelihood of allowing moisture to pass. The second insulating film 114 may be a film that is denser in texture than the first insulating film 111. The second insulating film 114 may contain silicon nitride (SiN), silicon oxide nitride (SiON), or the like, for example. Herein, the second insulating film 114 contains SiN from the standpoint of moisture resistance and shielding property against metal ions or other impurities. The second insulating film 114 may be a single-layered film of SiN. Alternatively, the second insulating film 114 may be a multilayer film including an SiN film; in this case, the SiN film in the second insulating film 114 may be in contact with the first insulating film 111.

A portion of the second insulating film 114 overlaps the first impurity region 151 via the first insulating film 111, while another portion overlaps a portion of the FLR structure 152R via the first insulating film 111. When viewed from the normal direction of the principal face of the semiconductor substrate 101, in a region further outward of the second insulating film 114, at least one ring 152 exists that is not covered by the second insulating film 114.

In the present specification, a face 114S of the second insulating film 114 that is in contact with the first insulating film 111 is referred to as the “first face”. The first face 114S of the second insulating film 114 is disposed so as to surround the active region 100M when viewed from the normal direction of the principal face of the semiconductor substrate 101. An edge 114a at the inner periphery side of the first face 114S is referred to as the “inner peripheral edge”, whereas an edge 114b at the outer periphery side of the first face 114S is referred to as the “outer peripheral edge”.

Examples of the inner peripheral edge 114a and the outer peripheral edge 114b of the first face 114S of the second insulating film 114 are illustrated in FIG. 1 with broken lines. In the present embodiment, when viewed from the normal direction of the semiconductor substrate 101, the inner peripheral edge 114a of the second insulating film 114 is disposed inward of the outer peripheral edge of the first impurity region 151. When viewed from the normal direction of the semiconductor substrate 101, the inner peripheral edge 114a of the second insulating film 114 may be located inside the first impurity region 151. On the other hand, when viewed from the normal direction of the principal face of the semiconductor substrate 101, the outer peripheral edge 114b of the second insulating film 114 is located between one of the plurality of rings 152 that is located innermost in the FLR structure 152R (“first ring 152a”) and one of the plurality of rings 152 that is located outermost in the FLR structure 152R (“second ring 152b”). Herein, the first ring 152a is one of the plurality of rings 152 in the FLR structure 152R that is the closest to the first impurity region 151, whereas the second ring 152b is one that is the farthest from the first impurity region 151.

In other words, when viewed from the normal direction of the principal face of the semiconductor substrate 101, the first face 114S of the second insulating film 114 extends so as to cover a portion of the first impurity region 151 and at least the first ring 152a among the plurality of rings 152. However, the extent of the first face 114S stops short of at least the second ring 152b; that is, the first face 114S does not cover the second ring 152b.

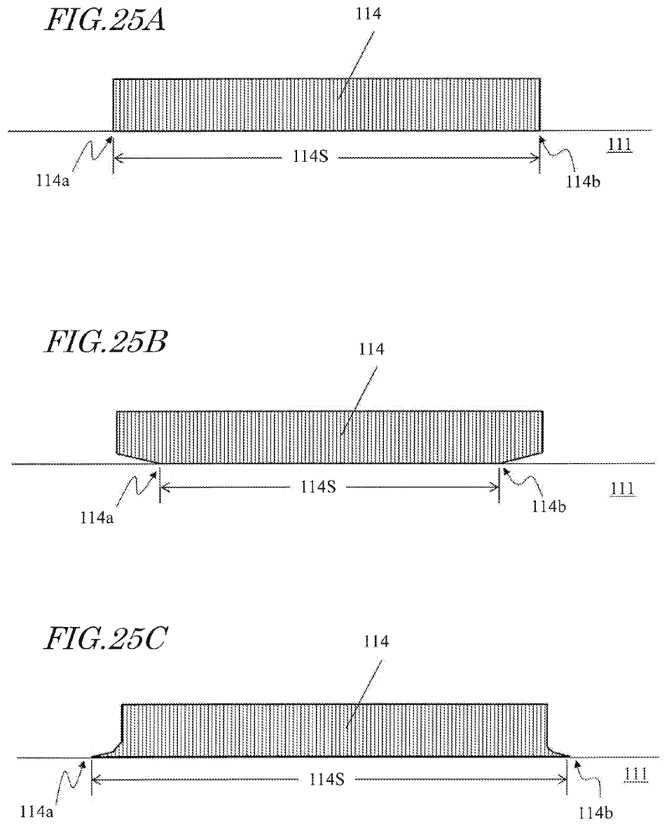

Note that the cross-sectional shape of the second insulating film 114 may vary depending on the etching condition when forming the second insulating film 114. For example, as shown in FIG. 25A, the second insulating film 114 may have a rectangular cross-sectional shape. Moreover, as shown in FIG. 25B, ends of the second insulating film 114 may be overetched so as to become lifted from the first insulating film 111. At each end of the second insulating film 114, the width of the portion that becomes lifted may be e.g. about 1 to about 2 μm. Furthermore, as shown in FIG. 25C, ends of the second insulating film 114 may be underetched such that side face of the second insulating film 114 appear tapered. In the examples shown in FIG. 25A and FIG. 25C, the entire lower face of the second insulating film 114 defines the first face 114S. In the example shown in FIG. 25B, a portion of the lower face of the second insulating film 114 that has not been lifted defines the first face 114S.

The third insulating film 115 is disposed so as to cover at least a portion of the first electrode 1120, the second insulating film 114, and at least a portion of the first insulating film 111. The third insulating film 115 is an organic insulating film such as polyimide, for example. When viewed from the normal direction of the principal face of the semiconductor substrate 101, the outer peripheral edge of the third insulating film 115 is located outward of the outer peripheral edge 114b of the second insulating film 114. The third insulating film 115 may cover the entire second insulating film 114.

Although not shown, the third insulating film 115 has an aperture through which a portion of the first electrode 1120 is exposed. This allows an external electrical contact to be made with the first electrode 1120. Alternatively, above the first electrode 1120 being exposed through an aperture in the third insulating film 115, a further metal electrode (e.g., plating) may be disposed.

Within the active region 100M and the termination region 100E, at the face (i.e., the rear face) of the semiconductor substrate 101 that is opposite to its face on which the semiconductor layer 102 is deposited, a second electrode 1130 to be electrically coupled thereto is disposed.

With such a configuration, the semiconductor device 1000 enables switching or rectification with a high breakdown voltage and low resistance between the first electrode 1120 and the second electrode 1130.

In the semiconductor device 1000, when viewed from the normal direction of the principal face of the semiconductor substrate 101, the inner peripheral edge 114a of the second insulating film 114 is disposed inward of the outer peripheral edge of the first impurity region 151, and the outer peripheral edge 114b is located between the first ring 152a and the second ring 152b. As will be described later, in the semiconductor device 1000, there is a particularly large field intensity at pn junction interfaces, i.e., the outer peripheral edge of the first impurity region 151 and the outer peripheral edge of the first ring 152a, where a leak current due to high temperature is likely to occur. In the semiconductor device 1000, the second insulating film 114 is disposed so as to cover such interfaces, thereby allowing a leak current due to high temperature to be reduced and improving high-temperature durability. Moreover, the second insulating film 114 does not extend to above the second ring 152b, thereby allowing a decrease in the moisture resistance of the semiconductor device 1000 to be suppressed. Details thereof will be described later.

Furthermore, in the semiconductor device 1000, the second insulating film 114 is not in contact with the upper face 1120S of the first electrode 1120. As will be described later, if the second insulating film 114 were in contact with the upper face 1120S of the first electrode 1120, cracks might occur in portions of the second insulating film 114 that are in contact with the first electrode 1120. On the other hand, in the semiconductor device 1000, the second insulating film 114 is not in contact with the upper face 1120S of the first electrode 1120, whereby occurrence of cracks in the second insulating film 114 can be suppressed.

(Schottky-Barrier Diode)

Hereinafter, by taking a Schottky-barrier diode (SBD) containing silicon carbide as an example, a more specific configuration of a semiconductor device according to the present embodiment will be described.

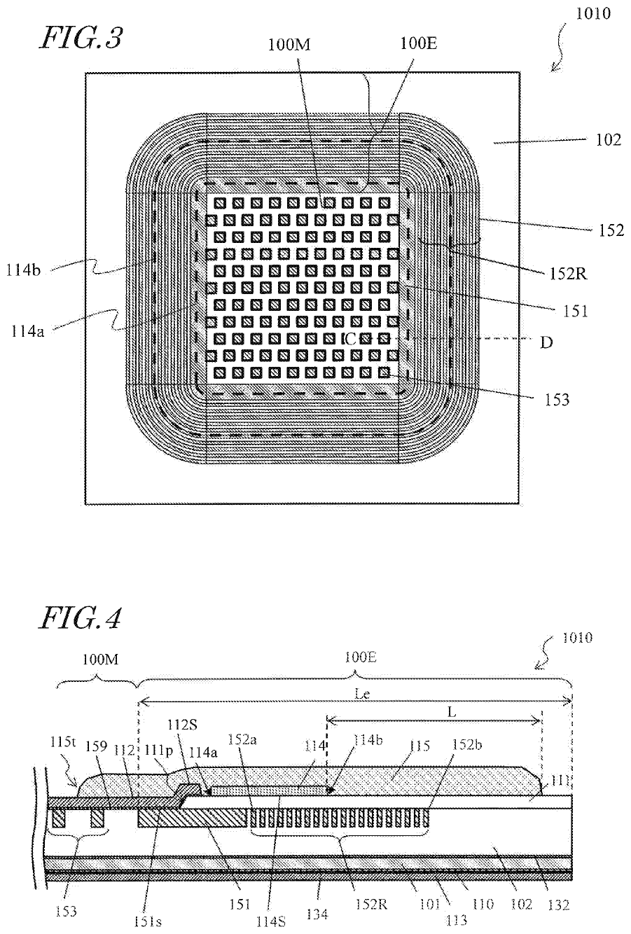

FIG. 3 and FIG. 4 are a plan view and a cross-sectional view, respectively, for schematically describing a semiconductor device (SBD) 1010 according to the present embodiment.

FIG. 3 shows the following elements of the semiconductor device 1010: an n type semiconductor layer (drift layer) 102; a p type first impurity region (guard ring region) 151; an FLR structure 152R including a plurality of p type rings 152; and a plurality of p type barrier regions 153. In a termination region 100E, the guard ring region 151 and the plurality of rings 152 are formed on the surface of the semiconductor layer 102. The guard ring region 151 is disposed so as to surround an active region 100M. In the active region 100M, the plurality of barrier regions 153 are formed on the surface of the semiconductor layer 102.

FIG. 4 shows a cross-sectional structure of a portion of the active region 100M of the semiconductor device 1010 and the termination region 100E, as taken along line C-D in FIG. 3. As shown in FIG. 4, the semiconductor device 1010 includes: a semiconductor substrate 101; a semiconductor layer 102 disposed on a principal face of the semiconductor substrate 101; a first electrode; a first insulating film 111; a second insulating film 114; and a third insulating film 115. The semiconductor substrate 101 is an n type silicon carbide substrate, for example. The semiconductor layer 102 is an n type silicon carbide semiconductor layer, for example.

The semiconductor substrate 101 is a low-resistance 4H—SiC (0001) substrate that is off-cut by 4 degrees in e.g. the <11-20> direction. The semiconductor device 1010 may include an n type buffer layer 132 between the semiconductor layer 102 and the semiconductor substrate 101. The buffer layer 132 is an n type silicon carbide layer, and has a higher impurity concentration than that of the semiconductor layer 102 (drift region). The buffer layer 132 may be omitted.

As described earlier, the surface of the semiconductor layer 102 includes the p type guard ring region 151, the plurality of p type rings 152, and the p type barrier regions 153. Within the semiconductor layer 102, an n type region where no such p type regions are formed is referred to as a “drift region”. The plurality of rings 152 are disposed at an interval from the guard ring region 151, so as to surround the guard ring region 151 at its periphery. The plurality of barrier regions 153 are disposed in the active region 100M, which is surrounded by the guard ring region 151.

The first electrode is disposed above a portion of the semiconductor layer 102. The first electrode may have a multilayer structure whose lowermost layer is a metal layer that forms a Schottky junction with the semiconductor layer 102, for example. Herein, as the first electrode, a Schottky electrode 159 and a front face electrode 112 are stacked on the semiconductor layer 102 in this order. The Schottky electrode 159 is in contact with a portion of the guard ring region 151, forming a Schottky junction with the semiconductor layer 102. The front face electrode 112 may mainly contain e.g. Al, whereas the Schottky electrode 159 may mainly contain e.g. Ti.

The first insulating film 111 is disposed on a portion of the semiconductor layer 102. The first insulating film 111 covers a portion of the guard ring region 151, and covers the plurality of rings 152. The first insulating film 111 has a first aperture 111p through which a portion 151s of the upper face of the first impurity region 151 is exposed. Within the first aperture 111p of the first insulating film 111, the Schottky electrode 159 is in contact with the portion 151s of the first impurity region 151. The first electrode including the Schottky electrode 159 and the front face electrode 112 may cover a portion of the upper face of the first insulating film 111 and the side walls of the first aperture 111p of the first insulating film 111. The first insulating film 111 may contain e.g. SiO₂.

The second insulating film 114 is disposed so as to cover at least a portion of the first insulating film 111. The lower face of the second insulating film 114 is in contact with the first insulating film 111. The second insulating film 114 is not in contact with an upper face 112S of the front face electrode 112, which defines an upper face of the first electrode. The second insulating film 114 has a higher moisture resistance than that of the first insulating film 111. The second insulating film 114 may contain e.g. SiN. When viewed from the normal direction of the principal face of the semiconductor substrate 101, the second insulating film 114 may be disposed so as to surround the active region 100M.

Examples of an inner peripheral edge 114a and an outer peripheral edge 114b of a portion (first face) 114S of the lower face of the second insulating film 114 that is in contact with the first insulating film 111 are illustrated by broken lines in FIG. 3. As has been described with reference to FIG. 1, when viewed from the normal direction of the principal face of the semiconductor substrate 101, the inner peripheral edge 114a of the second insulating film 114 is disposed inward of the outer peripheral edge of the first impurity region 151. When viewed from the normal direction of the principal face of the semiconductor substrate 101, the outer peripheral edge 114b of the second insulating film 114 is located between a first ring 152a that is located innermost among the plurality of rings 152 and a second ring 152b that is located outermost. In other words, when viewed from the normal direction of the principal face of the semiconductor substrate 101, the first face 114S of the second insulating film 114 extends so as to cover at least the first ring 152a among the plurality of rings 152, from above a portion of the first impurity region 151. However, the extent of the first face 114S stops short of at least the second ring 152b.

The third insulating film 115 is disposed so as to cover at least a portion of the front face electrode 112, the second insulating film 114, and at least a portion of the first insulating film 111. The third insulating film 115 has an aperture 115t through which a portion of the front face electrode 112 is exposed. This allows an external electrical contact to be made with the front face electrode 112. Alternatively, above the front face electrode 112 being exposed through an aperture 115t in the third insulating film 115, a further metal electrode (e.g., Ni plating) may be disposed. The third insulating film 115, which is made of an organic material, is provided in order to reduce the physical damage when sealing the semiconductor device 1010 with a resin. The third insulating film 115 is an organic protective film containing e.g. polyimide, polybenzoxazole, or the like.

At the face (i.e., the rear face) of the semiconductor substrate 101 that is opposite to its face on which the semiconductor layer 102 is deposited, an ohmic electrode 110 and a back face electrode 113 are disposed as a second electrode. The ohmic electrode 110 and the back face electrode 113 are electrically coupled to the rear face of the semiconductor substrate 101. Herein, the ohmic electrode 110 forms an ohmic junction with the rear face of the semiconductor substrate 101. In order to reduce the contact resistance between the semiconductor substrate 101 and the ohmic electrode 110, an n type rear implantation region 134 may be formed on the rear face of the semiconductor substrate 101. The ohmic electrode 110 may be a silicide electrode containing Ni silicide or Ti silicide. A silicide electrode can be formed by depositing an Ni film or Ti film on SiC and thereafter making it into a silicide through a heat treatment. The back face electrode 113 is deposited so as to cover the silicide electrode. As the back face electrode 113, for example, a multilayer electrode including layers of Ti/Ni/Ag in this order from the ohmic electrode 110 may be chosen.

By adopting such a configuration, a semiconductor device 1010 that is capable of rectification with a high breakdown voltage and low resistance between the front face electrode 112 and the back face electrode 113 can be realized.

<Characteristics of Semiconductor Device 1010>

High-Temperature Durability

First, high-temperature durability of the semiconductor device 1010 shown in FIG. 4 will be discussed.

In the semiconductor device 1010, when viewed from the normal direction of the principal face of the semiconductor substrate 101, the inner peripheral edge 114a of the second insulating film 114 is disposed inward of the outer peripheral edge of the guard ring region 151, whereas the outer peripheral edge 114b of the second insulating film 114 is located between the first ring 152a and the second ring 152b. As a result, above a portion of the surface of the semiconductor layer 102 that is located between the guard ring region 151 and the first ring 152a, the second insulating film 114 is disposed via the first insulating film 111. This allows high-temperature durability of the semiconductor device 1010 to be maintained.

The reason why the above configuration allows high-temperature durability to be maintained is as follows. When a positive bias (e.g. 1200 V) with respect to the front face electrode 112 is applied to the back face electrode 113), a high voltage in the reverse direction is applied to the pn junction between the p type guard ring region 151 and the n type drift region in the semiconductor layer 102. As a result, the pn junction interface between the guard ring region 151 and the drift region enters a high-field state. The plurality of rings 152 serve to extend a depletion layer from the pn junction interface to a greater extent in a parallel direction to the plane of the semiconductor substrate 101; this reduces the field intensity near the surface of the semiconductor layer 102 (i.e., near where the guard ring region 151 and the rings 152 are disposed), whereby the high breakdown voltage characteristics of the semiconductor device 1010 can be maintained. Since the field intensity becomes stronger at the pn junction interface, in the configuration of the semiconductor device 1010, for example, the field intensity becomes high at the outer peripheral edge of the guard ring region 151 or at the outer peripheral edge of the rings 152. In particular, the field intensity tends to increase at the outer peripheral edge of the guard ring region 151 ant at the outer peripheral edge of the first ring 152a. The inventors have found that, covering at least this region (i.e., from the outer peripheral edge of the guard ring region 151 to the outer peripheral edge of the first ring 152a) with the second insulating film 114 via the first insulating film 111 allows high-temperature durability to be maintained. As used herein, high-temperature durability refers to there being little leak current fluctuation after a high temperature reverse bias test (HTRB).

Now, the HTRB test will be specifically described. In general, a semiconductor device (power device) that can achieve a large current and high breakdown voltage is to be used while being incorporated in a generic package or a module. Therefore, a generic package product (TO247) having the semiconductor device 1010 mounted thereon is assembled. First, as an initial state, current-voltage characteristics at room temperature are ascertained. Thereafter, a high-temperature ambient at 175° C. is established as a stressing environment, and in this high-temperature environment, a rated voltage (e.g., 1200 V herein) is applied to the back face electrode 113 while keeping the front face electrode 112 at 0 V (ground). After a certain period of time passes, the temperature is brought down to room temperature, and voltage application is stopped. Thereafter, current-voltage characteristics are measured again at room temperature, and any change in static characteristics with respect to the initial value is determined. This is repeated, and the test is finished after the lapse of a predetermined time.

The inventors have consequently found that, in a semiconductor device lacking the second insulating film 114, the leak current may greatly increase over the initial value in a voltage range (e.g. 600 V) near appropriately a half of the rated voltage.

On the other hand, in the semiconductor device 1010, as will be described in detail later, increase in the leak current is suppressed in the HTRB test. In the semiconductor device 1010, via the first insulating film 111, the first face 114S of the second insulating film 114 covers at least above the first ring 152a which is adjacent to the guard ring region 151 and a subregion of the drift region that is located between the guard ring region 151 and the first ring 152a. As a result, even if moisture, charge, or charged particles such as ions that exist in the external environment or in a sealing resin (not shown) or the third insulating film 115 is attracted toward the high-field region of the semiconductor device 1010, the second insulating film 114 restrains intrusion of charge or the charged particles into the semiconductor layer 102.

Thus, as can be confirmed from the results of the HTRB test, a stable device operation can be realized even under the application of a high voltage, whereby not only leak fluctuations in the rated voltage can be restrained but also fluctuations in the leak current at or below the rated voltage can be suppressed.

Moisture Resistance

Next, moisture resistance of the semiconductor device 1010 will be discussed.

In conventional semiconductor devices, an SiN film may be used in order to obtain moisture resistance. The SiN film is to be disposed so as to cover approximately the entire area of the termination structure, including the FLR structure (see Patent Document 1).

FIG. 5 is a cross-sectional view showing a semiconductor device 9010 according to Comparative Example.

In the semiconductor device 9010 according to Comparative Example, the second insulating film 914 is covered by the third insulating film 115, and extends from a portion adjacent to the inner peripheral edge of the third insulating film 115 to a portion adjacent to the outer peripheral edge. When viewed from the normal direction of the principal face of the semiconductor substrate 101, the second insulating film 914 extends from above a portion of the upper face 112S of the front face electrode 112 to near the device end, covering approximately the entire area of the termination structure. This would be expected to suppress intrusion of moisture from above the semiconductor device 9010, and improve moisture resistance of the semiconductor device 9010. However, the inventors have found that the semiconductor device 9010 suffers from the following insufficiencies.

In the semiconductor device 9010, a portion of the second insulating film 914 is in contact with the upper face 112S of the front face electrode 112, which mainly contains Al. In such a structure, when the semiconductor device 9010 is incorporated into a generic package (such as TO247) and sealed with a resin, cracks may occur in portions of the second insulating film 914 that are in contact with the upper face 112S of the front face electrode 112 due to the stress associated with the assembly, even while the semiconductor device 9010 is not powered. This is presumably due to a difference in thermal expansion/contraction characteristics between the second insulating film 914 (e.g., an SiN film) and the first electrode (e.g., an Al electrode) 1120. Since the second insulating film 914 is an insulating film which is higher in moisture resistance (i.e., denser in texture) than the first insulating film 111, the second insulating film 914 is susceptible to cracks. Cracks occurring in the second insulating film 914 will deteriorate the moisture resistance of the second insulating film 914. Furthermore, the cracks may extend owing to environmental change and aging during use, possibly causing insufficiencies in the semiconductor device 9010.

On the other hand, in the semiconductor device 1010 according to the present embodiment, the second insulating film 114 is not in contact with the upper face 112S of the front face electrode 112. This solves the problem of cracks occurring in portions of the second insulating film 114 that are in contact with the upper face 112S of the front face electrode 112, thereby eliminating one of the causes for insufficiencies in the semiconductor device 1010.

Although not shown, the inner peripheral side face of the second insulating film 114 may be in contact with the outer peripheral side face of the front face electrode 112 (which is the first electrode). However, as shown in the figure, occurrence of cracks can be suppressed more effectively by disposing the second insulating film 114 at an interval from the first electrode so that the second insulating film 114 and the first electrode will not be in contact.

Moreover, in the semiconductor device 1010, within the termination region 100E, the third insulating film 115 extends from above a portion of the guard ring region 151 to near the device end, for example, so as to cover the entire FLR structure 152R. The outer peripheral edge 114b of the second insulating film 114 does not extend over to the second ring 152b, which is the farthest from the guard ring region 151. In other words, at least one ring 152 exists in the region outside the outer peripheral edge 114b of the second insulating film 114. This allows the outer peripheral edge 114b of the second insulating film 114 to be disposed at a distance from the outer peripheral edge of the third insulating film 115. This allows the moisture resistance of the semiconductor device 1010 to be maintained. As used herein, moisture resistance refers to there being little leak current fluctuation after a THB (Temperature Humidity Bias Test) or H3TRB (High Humidity High Temperature Reverse Bias Test).

Now, the THB test will be specifically described. In the THB test, as in the case of the HTRB test, a generic package product (TO247) having the semiconductor device 1010 mounted thereon is assembled. First, as an initial state, current-voltage characteristics at room temperature are ascertained. Thereafter, a high-temperature and high-humidity ambient at a temperature of 85° C. and a relative humidity of 85% is established as a stressing environment, and in this stressing environment, a voltage (e.g., 1000 V herein) which is about 80% of the rated voltage is applied to the back face electrode 113 while keeping the front face electrode 112 at 0 V (ground). After a certain period of time passes, humidification is stopped; the temperature is brought down to room temperature; and voltage application is stopped. Thereafter, current-voltage characteristics are measured again in the room-temperature and usual-humidity environment, and any change in static characteristics with respect to the initial values is determined. This is repeated, and the test is finished after the lapse of a predetermined time.

The inventors have consequently found that, when the semiconductor device 9010 according to Comparative Example shown in FIG. 5 is subjected to a THB test under a high-temperature and high-humidity environment, the leak current increases. The presumable reason thereof is as follows. In the semiconductor device 9010 according to Comparative Example, moisture, charge, or charged particles such as ions may reach the semiconductor device 9010 through the resin formed at the device periphery, thus intruding at the side face of the first insulating film 111 or portions of the surface of the first insulating film 111 that are not covered by the third insulating film 115. As described earlier, in the semiconductor device 9010, the second insulating film 914 extends over to near the outer peripheral edge of the third insulating film 115, so that the distance L between the outer peripheral edge of the second insulating film 914 and the outer peripheral edge of the third insulating film 115 is small (e.g. about 5 μm). Therefore, moisture, charge, and charged particles such as ions intruding into the first insulating film 111 may easily arrive below the outer peripheral edge of the second insulating film 914 through diffusion. The second insulating film 914 is made of e.g. SiN, and thus blocks moisture by nature; therefore, moisture, charge, and charged particles such as ions intruding from the first insulating film 111 may accumulate at the interface between the second insulating film 914 and the first insulating film 111. This results in a reduced closeness of contact at the interface between the second insulating film 914 and the first insulating film 111, so that the lift and/or delamination of the second insulating film 914 may progress owing to stress from the resin or the internal stress in the second insulating film 114 itself. When the second insulating film 914 sustains a lift and/or delamination, it may become even easier for moisture, charge and charged particles such as ions to intrude into the semiconductor device 9010, thereby further aggravating the lift and/or delamination of the second insulating film 914. Portions of the second insulating film 114 may be physically destroyed. This may possibly cause an increase in the leak current and a decrease in the breakdown voltage, etc., upon application of a high voltage.

On the other hand, in the semiconductor device 1010 according to the present embodiment shown in FIG. 4, as will be described in detail later, increase in the leak current is suppressed in the THB test. In the semiconductor device 1010, the outer peripheral edge of the third insulating film 115 is located outward of the outer peripheral edge 114b of the second insulating film 114, and the minimum distance L between the outer peripheral edge 114b of the second insulating film 114 and the outer peripheral edge of the third insulating film 115 in a plane parallel to the semiconductor substrate 101 may be set sufficiently larger than that of the semiconductor device 9010. Specifically, the distance L of the semiconductor device 1010 may be set to 65 μm or more, for example. When the distance L is sufficiently large, moisture, charge, and charged particles such as ions intruding from the side face of the first insulating film 111 or portions of the surface of the first insulating film 111 that are not covered by the third insulating film 115 is less likely to arrive below the outer peripheral edge of the second insulating film 114 even by diffusing into the first insulating film 111. As a result, occurrence of the aforementioned lift and/or delamination can be suppressed. Thus, according to the present embodiment, not only leak fluctuations in the rated voltage can be suppressed, but also fluctuations in the leak current at or below the rated voltage can be suppressed, whereby moisture resistance can be maintained.

Note that, in the semiconductor device 9010 according to Comparative Example, the second insulating film 914 is disposed so as to cover the entire FLR structure 152R, which makes it difficult to increase the distance L. In order to disposes the second insulating film 914 so as to cover the entire FLR structure 152R and yet make the distance L sufficiently large, it is necessary to increase the distance (i.e., the width of the termination region 100E) Le from the inner peripheral edge of the guard ring region 151 to the end of the semiconductor device 1010. However, increasing the distance Le while maintaining the size of the active region 100M may result in a larger size of the semiconductor device 9010, thus resulting in increased costs.

On the other hand, according to the present embodiment, the distance L from the outer peripheral edge 114b of the second insulating film 114 to the outer peripheral edge of the third insulating film 115 and the distance Le from the inner peripheral edge of the guard ring region 151 to the end of the semiconductor device 1010 can be independently set. Therefore, by making the distance L sufficiently large while keeping the distance Le small enough to suppress the costs associated with the semiconductor device 1010, moisture resistance can be provided. Specifically, as shown in FIG. 4, the second insulating film 114 may be disposed so that some rings 152 among the plurality of rings 152 are located outward of the outer peripheral edge 114b of the second insulating film 114, thereby simultaneously achieving a sufficiently large distance L and a not-too-large distance Le.

In Patent Document 1, the end of the SiN film at the inner periphery side is disposed in contact with the upper face of the Al electrode, so that cracks may occur in the SiN film, as is the case with the semiconductor device 9010 according to Comparative Example. Also in Patent Document 1, the SiN film formed on the SiO₂ film covers the entire FLR structure, thus extending to near the device end. This may cause, as described earlier, a lift and/or delamination in the SiN film at the device end owing to moisture, charge, and charged particles such as metal ions intruding from the SiO₂ film, and cracks may occur even at the device end owing to the stress associated with the assembly. As such cracks extend into the device interior, further deteriorations in moisture resistance may be caused.

<Variations of SBD>

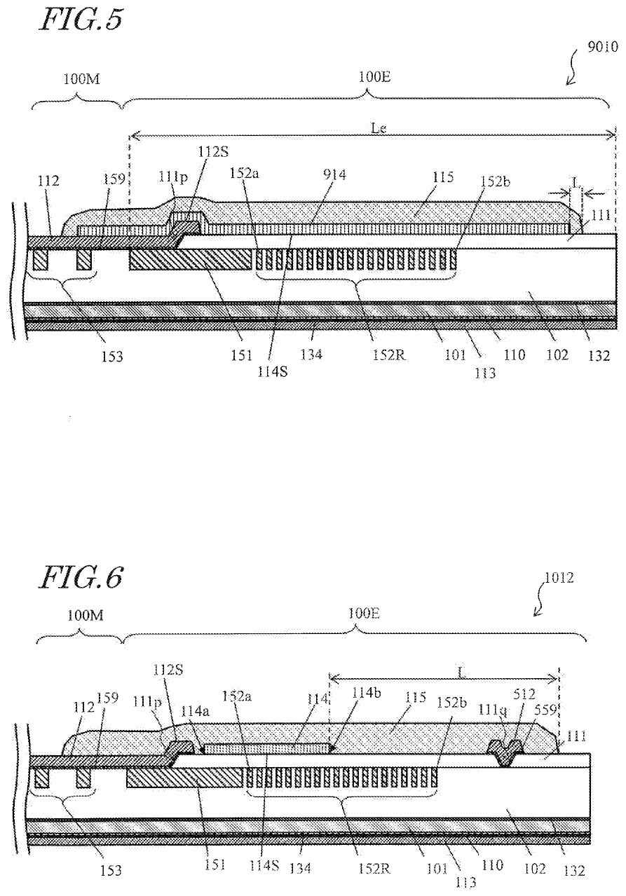

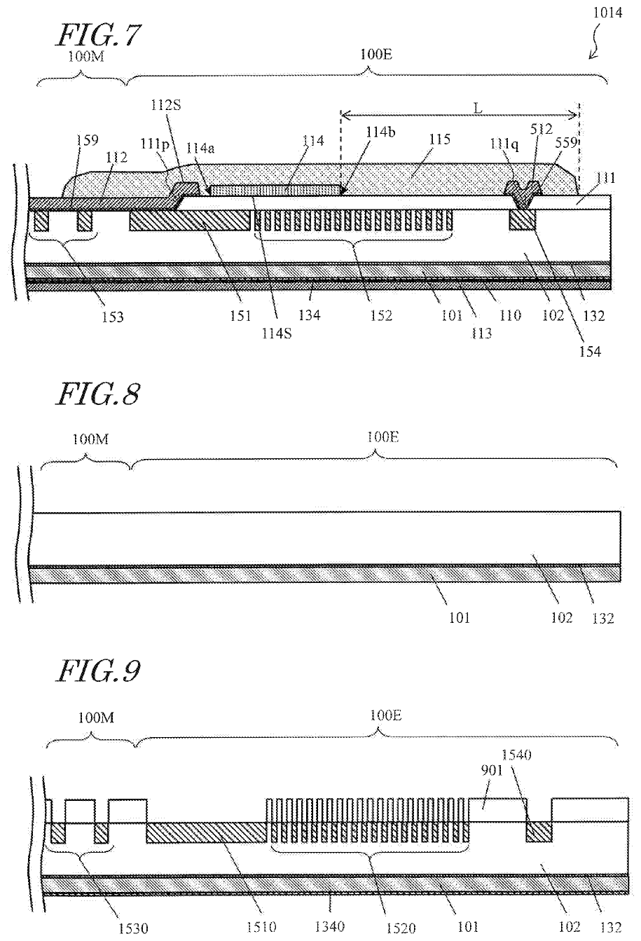

FIG. 6 and FIG. 7 are cross-sectional views illustrating still other semiconductor devices (SBD) 1012 and 1014 according to the present embodiment, showing a cross-sectional structure taken along line C-D shown in FIG. 3. Hereinafter, only the differences from the semiconductor device 1010 will be described.

With an aim to further improve moisture resistance, the semiconductor device 1012 shown in FIG. 6 includes a seal ring 512 outside the FLR structure 152R. A seal ring 512 may be formed at the lower face of a barrier metal 559. When viewed from the normal direction of the principal face of the semiconductor device 1012, the seal ring 512 may be disposed so as to surround the FLR structure 152R. In this example, the first insulating film 111 has a second aperture 111q through which a portion of the semiconductor layer 102 is exposed. The seal ring 512 is disposed in a portion of the upper face of the first insulating film 111 and in the second aperture 111q via a barrier metal 152B, and is electrically connected to the drift region via the barrier metal 152B. Presence of the seal ring 512 makes it even more difficult for the moisture, charge, and charged particles such as metal ions intruding from the side face of the first insulating film 111 or portions of the surface of the first insulating film 111 that are not covered by the third insulating film 115 to diffuse over to the second insulating film, whereby a further enhanced moisture resistance can be expected.

The semiconductor device 1014 shown in FIG. 7 differs from the semiconductor device 1012 shown in FIG. 6 in that, below the seal ring 512, a terminal implantation region 154 is formed at the surface of the semiconductor layer 102. The terminal implantation region 154 is formed through ion implantation of a p type or n type impurity to the semiconductor layer 102, for example. In this example, the second aperture 111q of the first insulating film 111 exposes a portion of the terminal implantation region 154. The seal ring 512 is disposed in a portion of the upper face of the first insulating film 111 and in the second aperture 111q via the barrier metal 152B, and is electrically connected to the terminal implantation region 154 via the barrier metal 152B.

(Method of Producing Semiconductor Device)

Next, with reference to the drawings, a method of producing a semiconductor device according to the present embodiment will be described. Herein, the semiconductor device (SBD) 1014 including a seal ring, shown in FIG. 7, will be taken as an example. Note that the other semiconductor devices 1010 and 1012 can also be produced by a similar method.

FIG. 8 to FIG. 16 are step-by-step cross-sectional views each describing a part of a method of producing the semiconductor device 1014 according to the present embodiment.

First, a semiconductor substrate 101 is provided. The semiconductor substrate 101 is a low-resistance substrate of, for example, the first conductivity type (n type) 4H—SiC (0001) having a resistivity of about 0.02 Ωcm, the substrate being off-cut by e.g. 4 degrees in the <11-20> direction.

Next, as shown in FIG. 8, on the semiconductor substrate 101, an n type semiconductor layer 102 is formed through epitaxial growth. The impurity concentration in the semiconductor layer 102 is lower than the impurity concentration in the semiconductor substrate 101. The semiconductor layer 102 is composed of an n type 4H—SiC, for example. The impurity concentration in the semiconductor layer 102 is e.g. 1×10¹⁶ cm⁻³, and the thickness of the semiconductor layer 102 is e.g. 11 μm. Before forming the semiconductor layer 102, an n type buffer layer 132 composed of an SiC with a high impurity concentration may be deposited on the semiconductor substrate 101. The impurity concentration in the buffer layer 132, e.g. 1×10¹⁸ cm⁻³, is higher than the impurity concentration in the semiconductor layer 102, and the thickness of the buffer layer 132 is e.g. 1 μm. The impurity concentrations and thicknesses of the semiconductor layer 102 and the buffer layer 132 are to be appropriately chosen in order to obtain a necessary breakdown voltage, without being limited to the above values.

Next, as shown in FIG. 9, a mask 901 of e.g. SiO₂ is formed on the semiconductor layer 102, and thereafter e.g. Al ions are implanted in the semiconductor layer 102. Thus, ion implantation regions 1510, 1520, 1530 and 1540 are formed in the semiconductor layer 102. The ion implantation regions 1510, 1520, 1530 and 1540 will later become, respectively, a guard ring region 151, rings 152 in an FLR structure 152R, barrier regions 153, and a terminal implantation region 154.

By forming the ion implantation region 1530, the semiconductor device 1014 acquires the structure of an SBD having a junction barrier, i.e., a JBS structure. The ion implantation region 1530 may be adapted to the need to reduce the leak current in the semiconductor device.

The ion implantation region 1530 is not essential. The mask 901 may not be apertured in a region corresponding to the ion implantation region 1530, thus preventing the ion implantation region 1530 from being formed. In this case, an SBD will result which has a similar termination structure to that of the semiconductor device 1014 but which lacks a junction barrier.

The ion implantation region 1540 to later become the terminal implantation region 154 may be adapted to the need to improve moisture resistance. In the case of producing the semiconductor device 1010 or 1012, the ion implantation region 1540 is not formed.

The ion implantation regions 1510, 1520, 1530 and 1540 do not need to be formed simultaneously, and may each be individually formed. In the case where these ion implantation region are allowed to have identical ion concentrations and depths, they may be formed simultaneously as illustrated in FIG. 9 in order to simplify the production steps. After the ion implantation, the mask 901 is removed.

By implanting an impurity of the first conductivity type (n type), e.g., phosphorus or nitrogen, to the rear face side of the semiconductor substrate 101 as necessary, an ion implantation region 1340 having a further enhanced first conductivity type concentration at the rear face may be formed.

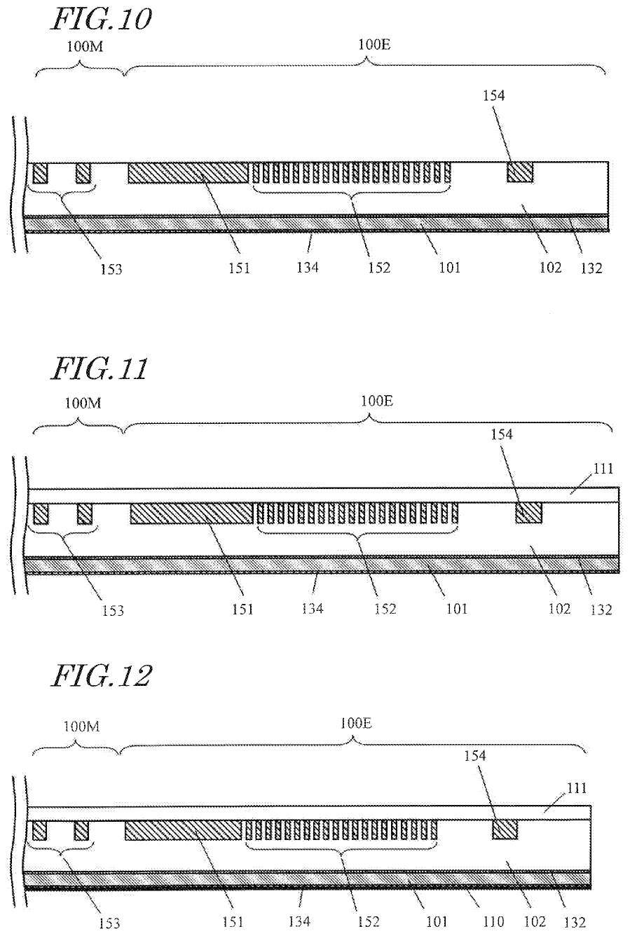

Thereafter, as shown in FIG. 10, a heat treatment is performed at a temperature of about 1500° C. to about 1900° C., whereby the guard ring region 151, the rings 152, the barrier regions 153, the terminal implantation region 154 of the second conductivity type (p type) are formed from the ion implantation regions 1510, 1520, 1530 and 1540, respectively, and also a rear implantation region 134 of the first conductivity type (n type) is formed.

At a position that is in contact with the surface of the semiconductor layer 102, the impurity concentration of the second conductivity type may be 1×10²⁰ cm⁻³ or more. By forming the guard ring region 151 and the FLR structure 152R in such high concentrations, a high breakdown voltage can be maintained.

The impurity concentration of the first conductivity type in the rear implantation region 134 may be e.g. 5×10¹⁹ cm⁻³ or more. This allows for reducing the contact resistance with an ohmic electrode that is subsequently formed.

Before performing a heat treatment, a thin film having high-temperature durability, e.g., a carbon film, may be deposited on the surface of the semiconductor layer 102, and the carbon film may be removed after the heat treatment. Thereafter, a thermal oxide film may be formed on the surface of the semiconductor layer 102, and the thermal oxide film may then be etched away, thereby cleaning the surface of the semiconductor layer 102.

The guard ring region 151 is disposed so as to surround the active region 100M shown in FIG. 1 or FIG. 3. In a plane parallel to the semiconductor substrate 101, the width from the inner peripheral edge of the guard ring region 151 to the outer peripheral edge is e.g. 16 μm. The width from the inner peripheral edge to the outer peripheral edge of the plurality of rings 152 is e.g. 1 μm. The interval between adjacent rings 152 is e.g. not less than 0.8 μm and not more than 5 μm. The width of each ring 152 and the interval between adjacent rings 152 may have fixed values, or may be allowed to vary in order to realize a desired breakdown voltage of the semiconductor device. In the present embodiment, the rings 152 all have a width of 1 μm, and the interval between adjacent rings 152 is set at an equal (or greater) interval from the inner periphery side toward the outer periphery side. Moreover, in the present embodiment, the number of rings 152 in the FLR structure 152R is 25. This number may be changed in order to realize a desired breakdown voltage, and may be not smaller than 10 and not greater than 30. In the termination region 100E including the guard ring region 151 and the FLR structure 152R, the maximum concentration of the impurity of the second conductivity type is e.g. about 2×10²⁰ cm⁻³, and the depth of the guard ring region 151 and the FLR structure 152R is e.g. 1 μm.

The depth of the impurity of the second conductivity type is defined as follows. An impurity region of the second conductivity type is formed by implanting impurity ions of the second conductivity type to the semiconductor layer 102, for example. At this time, if the impurity concentration of the second conductivity type is plotted in the depth direction from the surface, the concentration will exhibit a value that is defined by the ion implantation conditions to a certain depth. The defined value is higher than that of the impurity concentration of the first conductivity type in the semiconductor layer 102. On the other hand, the implanted ions do not reach deep regions; therefore, the concentration will decrease in deep regions. Now, it is assumed that the impurity concentration of the first conductivity type in the semiconductor layer 102 is constant, e.g. 1×10¹⁶ cm⁻³, along the depth direction. If the impurity concentration of the second conductivity type is equal to the impurity concentration of the first conductivity type (1×10¹⁶ cm⁻³) at a certain depth and does not exceed the impurity concentration of the first conductivity type (1×10¹⁶ cm⁻³) in any deeper regions, then this depth is defined as the depth of the impurity of the second conductivity type.

Moreover, the width of the barrier regions 153 in a plane parallel to the semiconductor substrate 101 is e.g. 2 μm. The barrier regions 153 may be disposed at an interval of not less than 2 μm and not more than 6 μm. The shape of the barrier regions 153 and the interval at which they are disposed are to be appropriately chosen in order to realize desired characteristics of the semiconductor device 1014.

Furthermore, in the example shown in FIG. 10, the width of the terminal implantation region 154 in a plane parallel to the semiconductor substrate 101 is e.g. 11 μm, and is spaced apart from the second ring being located at the outermost periphery of the FLR structure 152R by e.g. about 9 μm.

Next, as shown in FIG. 11, a first insulating film 111 made of e.g. SiO₂ is formed on the surface of the semiconductor layer 102. The thickness of the first insulating film 111 is e.g. 1400 nm.

After protecting the surface of the semiconductor layer 102 with the first insulating film 111, as shown in FIG. 12, about 150 nm of e.g. Ti is deposited on the rear face of the semiconductor substrate 101, after which a heat treatment is performed at about 1000° C. to form the ohmic electrode 110. The ohmic electrode 110 forms an ohmic junction with the rear face of the semiconductor substrate 101. The electrode species is not limited to Ti, and any metal that can form a silicide, e.g. Ni or Mo, may be chosen.

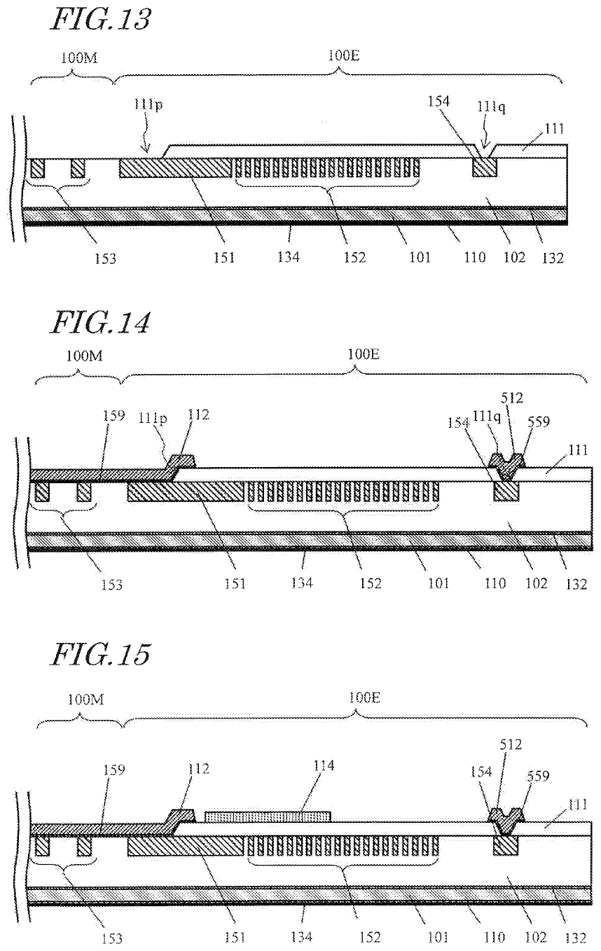

Next, a mask of photoresist (not shown) is formed, and the first insulating film 111 is etched. Herein, a wet etching is performed by using an etchant containing BHF, for example. Thus, as shown in FIG. 13, a first aperture 111p and a second aperture 111q are formed in the first insulating film 111. The first aperture 111p exposes a portion of the guard ring region 151 and a portion of the region of the semiconductor layer 102 that is located inside the guard ring region 151. The second aperture 111q exposes a portion of the terminal implantation region 154. Thereafter, the mask is removed.

The method of aperturing the first insulating film 111 is not limited to wet etching, and a dry etching using an etching gas, e.g., a CF₄ gas or an O₂ gas, or a combination of dry etching and wet etching may be employed. In the case where a combination of dry etching and wet etching is employed, the first insulating film 111 may be somewhat etched away through dry etching first, and the remainder may be removed through wet etching; as a result, dry etching damage to the surface of the semiconductor layer 102 can be avoided, whereby the leak current in the semiconductor device to be subsequently formed can be suppressed.

Next, on the first insulating film 111, an electrically conductive film for the Schottky electrode not shown is formed. The electrically conductive film for the Schottky electrode is deposited so as to cover the first insulating film 111, and to cover the entire face the portions of the semiconductor layer 102 that are exposed through the first aperture 111p and the second aperture 111q. The electrically conductive film for the Schottky electrode is a metal that can form a Schottky barrier with the semiconductor layer 102. The electrically conductive film for the Schottky electrode may be a Ti film, an Ni film, or an Mo film, or example, with a thickness of e.g. 200 nm. In the present embodiment, a Ti film is chosen.

After depositing the electrically conductive film for the Schottky electrode, the semiconductor substrate 101 having the electrically conductive film for the Schottky electrode formed thereon is subjected to a heat treatment, at a temperature of not lower than 100° C. and not higher than 700° C. As a result, the electrically conductive film for the Schottky electrode forms a Schottky junction with a portion of the exposed area of the semiconductor layer 102 in which the barrier regions 153 and the terminal implantation region 154 are not formed.

Next, above the electrically conductive film for the Schottky electrode, an electrically conductive film for the front face electrode (not shown) is deposited over the entire face. The electrically conductive film for the front face electrode is a metal film of about 3 to about 6 μm containing Al, for example.

Then, a mask (not shown) is formed on the electrically conductive film for the front face electrode, and unnecessary portions of the electrically conductive film for the Schottky electrode and the electrically conductive film for the front face electrode are etched, thereby exposing portions of the first insulating film 111. This etching may be wet etching or dry etching. After the electrically conductive film for the front face electrode and the Schottky electrode film are etched, the mask is removed. Thus, as shown in FIG. 14, the front face electrode 112 and the Schottky electrode 159 are formed on a portion of the first insulating film 111 and in the first aperture 111p.

At this point, at the end of the semiconductor substrate 101, a barrier metal 559 may be formed from the electrically conductive film for the Schottky electrode, onto a portion of the first insulating film 111 and in the second aperture 111q; and a seal ring 512 may be formed from the electrically conductive film for the front face electrode. According to this method, the Schottky electrode 159 and the barrier metal 559 are made of the same electrically conductive film, thereby having the same composition (i.e., sharing the same material). For example, if the Schottky electrode 159 is a thin metal film which is mainly composed of Ti, the barrier metal 559 will also be a thin metal film which is mainly composed of Ti. If the metal species of the Schottky electrode 159 is another metal, the barrier metal 559 will also be that metal. Moreover, the front face electrode 112 and the seal ring 512 are made of the same electrically conductive film, and therefore have the same composition, i.e., the same material. For example, if the front face electrode 112 is a metal containing Al, the seal ring 512 will also be a metal containing Al.

Next, at the side of the semiconductor substrate on which the front face electrode 112 is disposed, a second insulating film 114 of e.g. SiN is formed so as to cover the front face electrode 112 and the first insulating film 111. The thickness of the SiN film is e.g. 1.3 μm. Next, after a mask is formed on the SiN film, unnecessary portions of the SiN film are removed through dry etching. Thus, as shown in FIG. 15, the second insulating film 114 is formed on a portion of the first insulating film 111. The second insulating film 114 is disposed at an interval of e.g. 2 μm from the outer peripheral edge of the front face electrode 112 so as not to be in contact with the front face electrode 112. Via the first insulating film 111, the second insulating film 114 covers a portion of the guard ring region 151 and some rings 152 in the FLR structure 152R. In a plane parallel to the semiconductor substrate 101, the width from the inner peripheral edge to the outer peripheral edge of the second insulating film 114 is e.g. 24 μm.

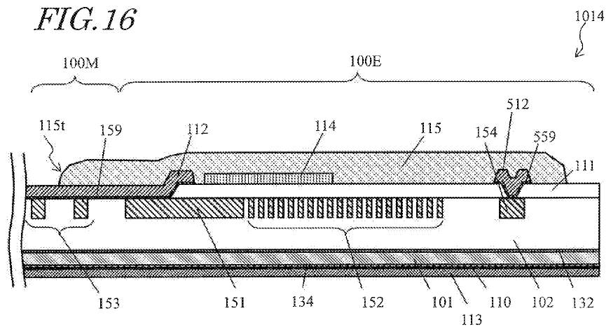

Next, as shown in FIG. 16, third insulating film 115, which is an organic film of polyimide or the like, is formed on the entire face so as to cover the front face electrode 112, the second insulating film 114, and the first insulating film 111. Thereafter, an aperture 115t through which to expose a portion of the front face electrode 112 is formed in the third insulating film 115, and also a region corresponding to the end of the semiconductor device is apertured to expose a portion of the first insulating film 111. The entire second insulating film 114 is covered by the third insulating film 115. In the case of forming the seal ring 512, the seal ring 512 may also be covered by the third insulating film 115. As the third insulating film 115, an organic protective film to be used in commonly-used semiconductor power devices, e.g., polyimide or polybenzoxazole, may be adopted.

Finally, a back face electrode 113 is formed as necessary. The step of forming the back face electrode 113 may be performed before the step of forming the aforementioned third insulating film 115, or before the step of forming the front face electrode 112. The back face electrode 113 is formed by depositing Ti, Ni, and Ag in this order from the side that is in contact with the ohmic electrode 110, for example. The respective thicknesses of Ti, Ni, and Ag are 0.1 μm, 0.3 μm, and 0.7 μm, for example. Through the above steps, the semiconductor device 1014 is produced.

The semiconductor device 1010 is produced by a similar method to the above except for not forming the terminal implantation region 154 and the seal ring 512. The semiconductor device 1012 is produced by a similar method to the above except for not forming the terminal implantation region 154.

### Example

The inventors have produced semiconductor devices according to Example, and examined their high-temperature durability and moisture resistance.

The semiconductor devices according to Example are Schottky-barrier diodes using SiC which allows a forward current of 50 A or more and a reverse breakdown voltage of 1200 V or higher applied thereto. In this Example, through the method described with reference to FIG. 8 to FIG. 16, 22 semiconductor devices having a similar configuration to that of the semiconductor device 1014 shown in FIG. 7 were produced. In each semiconductor device, the distance L between the outer peripheral edge of the second insulating film 114 and the outer peripheral edge of the third insulating film 115 was 95 μm. Then, generic packages (TO247) were fabricated in which the respective semiconductor devices were mounted, and then subjected to the aforementioned HTRB test and THB test.

Herein, a forward-direction ON voltage when applying 50 A in the forward direction (which is defined as the direction of current flowing from the front face electrode to the back face electrode) at room temperature is defined as “Vf50”. Moreover, reverse currents which flow when 600 V and 1200 V are applied to the back face electrode 113 (where the front face electrode 112 is assumed to be at 0 V) at room temperature are defined as “Ir600” and “Ir1200”, respectively.

In each test, values (initial values) of Vf50, Ir600 and Ir1200 before stress application, and Vf50, Ir600 and Ir1200 after stress application over a certain period of time (HTRB or THB), were respectively measured. Then, rates of change ΔVf50, ΔIr600 and ΔIr1200 for Vf50, Ir600 and Ir1200 were determined by the following formulae. Each test was performed until the duration of stress reached 2000 hours.

ΔVf50=Vf50 (after stress application)/Vf50 (initial value: before stress application)

ΔIr600=Ir600 (after stress application)/Ir600 (initial value: before stress application)

ΔIr1200=Ir1200 (after stress application)/Ir1200 (initial value: before stress application)

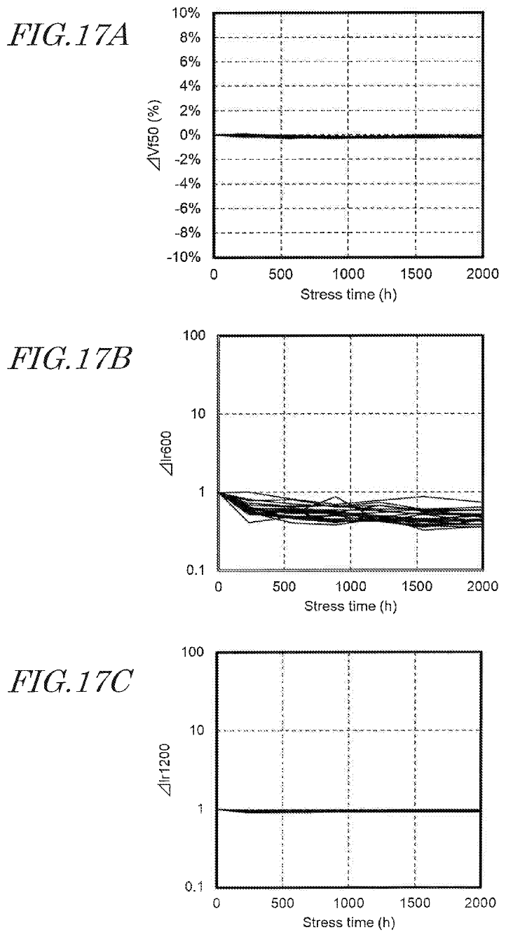

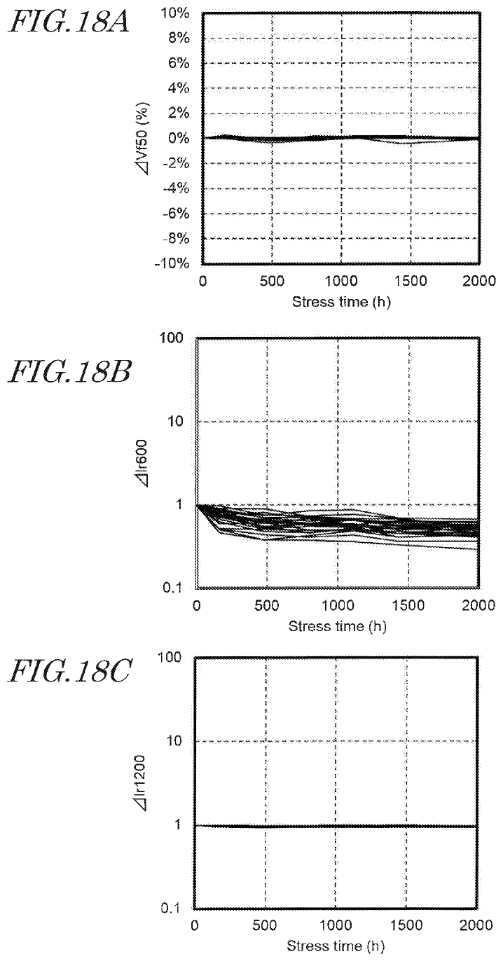

FIGS. 17A to 17C and FIGS. 18A to 18C are graphs respectively showing results of the HTRB test and the THB test for the semiconductor devices according to Example. FIG. 17A, FIG. 17B and FIG. 17C respectively show ΔVf50, ΔIr600 and ΔIr1200 in the HTRB test for each semiconductor device. FIG. 18A, FIG. 18B and FIG. 18C respectively show ΔVf50, ΔIr600 and ΔIr1200 in the THB test for each semiconductor device. In the graph of each figure, the vertical axis represents the rates of change ΔVf50, ΔIr600 and ΔIr1200, whereas the horizontal axis represents the duration of stress (stress time).

From the results shown in FIG. 17A, it was confirmed that the rate of change ΔVf50 for Vf50 was within ±10% in the HTRB test, indicative of suppression of fluctuations in the ON voltage. From the results shown in FIG. 17B and FIG. 17C, it was confirmed that the rates of change ΔIr600 and ΔIr1200 for Ir600 and Ir1200 were maintained at approximately×1 or smaller, indicative of suppression of an increase in the leak current.

Similarly, from the results shown in FIG. 18A to FIG. 18C, it was confirmed that characteristic fluctuations in the THB test were also suppressed, and in particular that an increase in the leak current was suppressed.

Note that the differences between samples are greater for ΔIr600 than for ΔIr1200 in both tests. This is presumably because the leak current at 600 V has an absolute value which is considerably smaller than the absolute value of the leak current at 1200 V, and thus is more susceptible to minute fluctuations in the measurement system, or to fluctuations in the minute leaks associated with changes in the electrically insulative property of the resin existing between the anode-cathode terminals of the TO247 package.

Thus, it became clear that, in the semiconductor devices according to the present embodiment, providing the second insulating film 114 at an appropriate position can suppress fluctuations in the ON voltage and the increase in the leak current in the HTRB test and the THB test.

The configurations of semiconductor devices according to the present disclosure and the materials of the constituent elements thereof are not limited to the configurations and materials illustrated above. For example, the material of the Schottky electrode 159 is not limited to Ti, Ni, and Mo as exemplified above. For the Schottky electrode 159, a material selected from the group consisting of any other metal that can form a Schottky junction with the semiconductor layer 102, and alloys and compounds thereof, may be used.

Moreover, a barrier film containing e.g. TiN may be formed between the Schottky electrode 159 and the front face electrode 112. The thickness of the barrier film is e.g. 50 nm.

(MISFET)

Semiconductor devices according to the present embodiment are not limited to Schottky diodes. The device structure according to the present embodiment is also applicable to MISFETs.

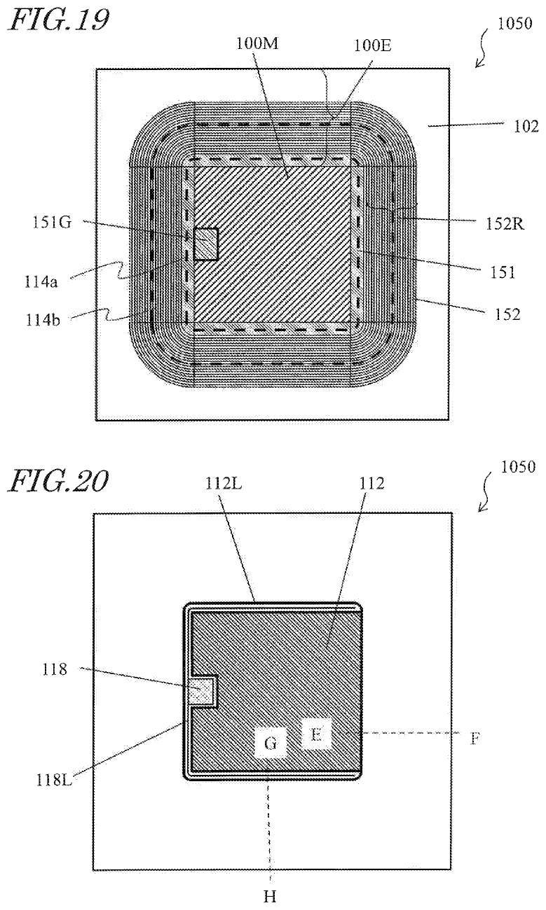

FIG. 19 and FIG. 20 are plan views for schematically describing a semiconductor device (MISFET) 1050 according to the present embodiment. In the following description, constituent elements which are of the same configurations and serve the same roles as those of the semiconductor device(s) described above will be denoted by the same reference numerals, and their description may be omitted.

FIG. 19 shows the following elements of the semiconductor device 1050: a semiconductor layer (drift layer) 102 of a first conductivity type; a first impurity region 151 of a second conductivity type and a plurality of rings 152 of the second conductivity type formed at the surface of the semiconductor layer 102 within a termination region 100E; and a first impurity region 151G for the pad, which is of the second conductivity type. The plurality of rings 152 are formed outside the guard ring region 151. The first impurity region 151G for the pad is disposed below a gate pad 118 (shown in figures to be mentioned later) that is needed when the semiconductor device 1050 is to function as a MISFET (or as a MOSFET). The region that is surrounded by the first impurity region 151 but excludes the first impurity region 151G for the pad defines an active region (primary conducting region, or effective region) 100M. In the active region 100M, a plurality of unit cells 1050U (shown in figures to be mentioned later) composing an MISFET are periodically disposed.

FIG. 20 shows the following elements of the semiconductor device 1050: a source pad 112; a source line 112L connected to the source pad 112; a gate pad 118; and a gate line 118L connected to the gate pad 118. In the present specification, the source pad 112 and the source line 112L may be collectively referred to as an “upper source electrode”, whereas the gate pad 118 and the gate line 118L may be collectively referred to as an “upper gate electrode”. The upper source electrode and the upper gate electrode are provided above the semiconductor layer 102, and are electrically insulated from each other.

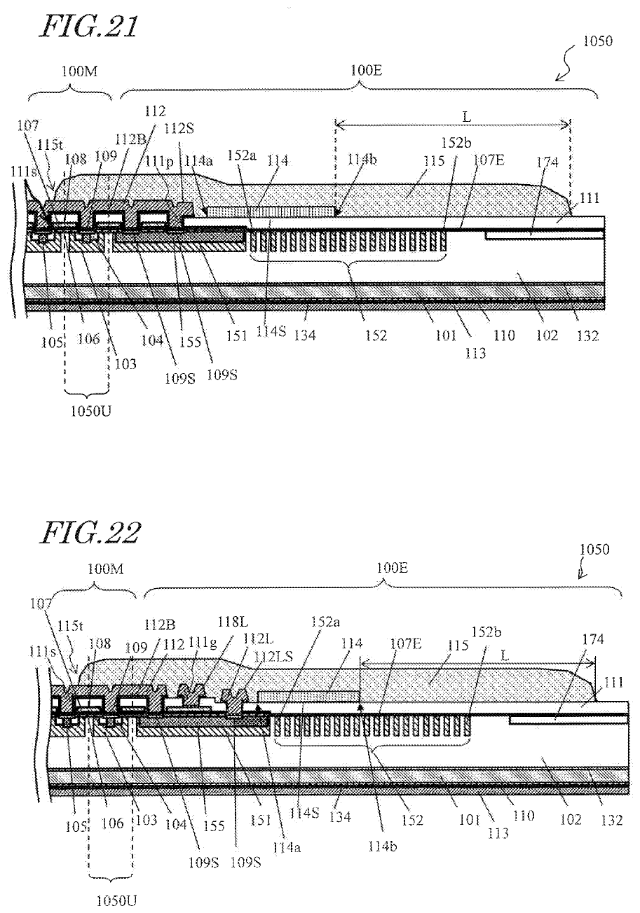

FIG. 21 and FIG. 22 are cross-sectional views of the semiconductor device 1050. FIG. 21 shows the cross-sectional structure from a portion of an active region 100M to the device end, as taken along line E-F in FIG. 20. FIG. 22 shows the cross-sectional structure from a portion of the active region 100M, across the source line 112L and the gate line 118L, to the device end, as taken along line G-H in FIG. 20. The cross-sectional structure shown in FIG. 22 differs from the cross-sectional structure shown in FIG. 21 in that the former is taken across the source line 112L and the gate line 118L.

As shown in FIG. 21 or FIG. 22, the semiconductor device 1050 includes: a semiconductor substrate 101 which is an n type silicon carbide substrate; and a semiconductor layer 102 which is an n type silicon carbide semiconductor layer disposed on a principal face of the semiconductor substrate 101. The semiconductor substrate 101 is a low-resistance 4H—SiC (0001) substrate that is off-cut by 4 degrees in e.g. the <11-20> direction. The semiconductor device 1050 may include an n type buffer layer 132 between the semiconductor layer 102 and the semiconductor substrate 101. The buffer layer 132 is an n type silicon carbide layer, and has a higher impurity concentration than that of the drift region. The buffer layer 132 may be omitted.

First, the structure of the active region 100M of the semiconductor device 1050 will be described. In the active region 100M, a plurality of MISFET unit cells 1050U are arrayed.

Each unit cell 1050U includes: a p type body region 103 selectively formed on the surface of the semiconductor layer 102; an n type source region 104 disposed inside the body region 103; a gate insulating film 107 located on the semiconductor layer 102; a gate electrode 108 located on the gate insulating film 107; and a drain electrode 110 disposed on the rear face of the semiconductor substrate 101. The region of the semiconductor layer 102 where the body regions 103 are not formed defines an n type drift region.

Although not shown in FIG. 21 and FIG. 22, in order to reduce the ON resistance when the semiconductor device 1050 operates as a MISFET, an n type JFET region having a higher impurity concentration than that of the drift region may be formed in a portion of the drift region that is located between adjacent unit cells 1050U. The impurity concentration in the JFET region may be e.g. 1×10¹⁷ cm⁻³.

In the semiconductor device 1050, the p type impurity concentration near the surface of the body regions 103 may be about 1.5×10¹⁹ cm⁻³, and the depth of the body regions 103 may be about 1 μm. Herein, the body regions 103 may contain e.g. Al as the p type impurity. The interval between adjacent body regions 103 may be e.g. about 1 μm.

Each source region 104 is selectively disposed on the surface of the corresponding body region 103, so as to be in ohmic contact with a source electrode 109. The source regions 104 contain an n type impurity at a higher concentration than that in the drift region. The n type impurity concentration near the surface of the source regions 104 may be about 5×10¹⁹ cm⁻³, and the depth of the source regions 104 may be about 200 nm. Herein, the source regions 104 may contain e.g. N or P as the n type impurity.

As viewed from above the semiconductor device 1050, a p type impurity region (contact region) 105 may be provided. The contact region 105 is adjacent to each source region 104 and contains a p type impurity at a higher concentration than in the body region 103. The contact region 105 extends to below the lower end of the source region 104, so as to be connected to the body region 103. The p type impurity concentration near the surface of the contact region 105 may be about 1×10²⁰ cm⁻³, and the depth of the contact region 105 may be about 400 nm. Herein, the contact region 105 may contain e.g. Al as the p type impurity.

On the semiconductor layer 102, a channel layer 106 containing an n type silicon carbide (SiC) may be provided. The channel layer 106 may be an epitaxial layer that is formed through epitaxial growth on the semiconductor layer 102. The channel layer 106 may be formed by, for example, forming an SiC epitaxial layer on the entire upper face of the semiconductor layer 102, and thereafter removing portions of the SiC epitaxial layer that are located in portions other than predetermined regions. Herein, by removing portions of the SiC epitaxial layer that are located outward of the first impurity region 151, the channel layer 106 is formed in the active region 100M and a portion of the termination region 100E. The thickness of the channel layer 106 may be e.g. not less than 30 nm and not more than 100 nm, and the average impurity concentration in the channel layer 106 may be e.g. not less than 1×10¹⁶ cm⁻³ and not more than 5×10¹⁸ cm⁻³. The thickness and the impurity concentration of the channel layer 106 are to be appropriately chosen in order to adjust the threshold voltage when the semiconductor device 1050 undergoes a transistor operation.

The gate insulating film 107 is disposed on the channel layer 106. The gate insulating film 107 may be formed through thermal oxidation of the channel layer 106 being made of silicon carbide, or formed by separately depositing an insulating film on the semiconductor layer 102 through CVD or the like. When the gate insulating film 107 is formed, an insulating film 107E is also formed above the region where the channel layer 106 has been removed. That insulating film 107E may be removed, or allowed to remain. The gate insulating film 107 mainly contains e.g. SiO₂. The thickness of the gate insulating film 107 may be e.g. about 70 nm.

The gate electrodes 108 are disposed on the gate insulating film 107. Each gate electrode 108 may be e.g. an n type low-resistance polysilicon layer. In this case, the gate electrodes 108 may be formed by depositing a polysilicon film with a thickness of about 500 nm on the gate insulating film 107, and removing unnecessary portions.

When viewed from the normal direction of the principal face of the semiconductor substrate 101, each gate electrode 108 covers a portion of the body region 103 that is located between the source region 104 and the drift region. This portion function as a channel of the MISFET.

The upper and side faces of each gate electrode 108 are covered by a first insulating film 111. The first insulating film 111 may be e.g. an SiO₂ film having a thickness of 1.4 μm. In each unit cell 1050U, the first insulating film 111 has a source aperture 111s through which a portion of the source region 104 and the contact region 105 are exposed.

The source electrode 109 is disposed in the source aperture 111s made in the first insulating film 111, so as to form ohmic junctions with the source regions 104 and the contact region 105 within the source aperture 111s. The body region 103 is electrically connected with the source electrode 109 via the contact region 105. The source electrode 109 mainly contains e.g. Ni. The source electrode 109 may be an Ni silicide electrode.

In the present embodiment, the source electrode 109 may be formed in the following manner, for example. First, Ni is deposited by e.g. about 100 nm in the source aperture 111s of the first insulating film 111. Next, a heat treatment is performed at a temperature of about 1000° C., thereby allowing Ni to react with the channel layer 106 into a silicide. Thus, as the source electrode 109, an Ni silicide electrode that forms ohmic junctions with the source regions 104 and the contact region 105 is obtained. Note that a portion of the channel layer 106 to be located in the source aperture 111s of the first insulating film 111 may be previously etched away. In this case, Ni may be allowed to react with the semiconductor layer 102 into a silicide.

On the source electrode 109, a barrier metal 112B and a source pad 112 are provided. The barrier metal 112B and the source pad 112 may be disposed so as to cover a portion of the upper face of the first insulating film 111 and the side face of the source aperture 111s. The source pad 112 is electrically connected with the source electrode 109 via the barrier metal 112B. The source pad 112 mainly contains e.g. Al. The barrier metal 112B contains e.g. Ti. The barrier metal 112B may have a multilayer structure of a TiN film and a Ti film, for example. The thickness of the TiN film may be 80 nm and the thickness of the Ti film may be 40 nm; and the TiN film may be in contact with the source pad 112, and the Ti film may be in contact with the source electrode 109.

At the face (i.e., the rear face) of the semiconductor substrate 101 that is opposite to its face on which the semiconductor layer 102 is deposited, an ohmic electrode (drain electrode) 110 and a back face electrode 113 are disposed as a second electrode. The drain electrode 110 and the back face electrode 113 are electrically coupled to the rear face of the semiconductor substrate 101. Herein, the drain electrode 110 forms an ohmic junction with the rear face of the semiconductor substrate 101. In order to reduce the contact resistance between the semiconductor substrate 101 and the drain electrode 110, an n type rear implantation region 134 may be formed on the rear face of the semiconductor substrate 101. The drain electrode 110 may be a silicide electrode containing Ni silicide or Ti silicide. A silicide electrode can be formed by depositing an Ni film or a Ti film on SiC, and thereafter making it into a silicide through a heat treatment. The back face electrode 113 is deposited so as to cover the silicide electrode. As the back face electrode 113, for example, a multilayer electrode containing Ti/Ni/Ag in this order from the drain electrode 110 may be chosen.

Next, the structure of the termination region 100E of the semiconductor device 1050 will be described.

In the termination region 100E, the surface of the semiconductor layer 102 includes: a p type first impurity region 151; and an FLR structure 152R including a plurality of p type rings 152. The plurality of rings 152 are disposed so as to surround the first impurity region 151 at its periphery. The first impurity region 151 may have a base contact region 155 on its surface, the base contact region 155 containing a p type impurity at a high concentration. This allows the concentration at the surface of the first impurity region 151 to be enhanced, and the resistance of the first impurity region 151 to be reduced. The concentration near the surface of the base contact region 155 is e.g. 1×10²⁰ cm⁻³ or more.

Moreover, the surface of the semiconductor layer 102 may include an n type impurity region 174. When viewed from the normal direction of the principal face of the semiconductor substrate 101, the impurity region 174 is disposed outward of the plurality of rings 152. The impurity region 174 contains e.g. N as the n type impurity. The depth of the impurity region 174 may be about 200 nm, and the impurity concentration may be about 5×10¹⁹ cm⁻³.

In order to simplify the production steps, the first impurity region 151 and the plurality of rings 152 may be formed simultaneously with the body region 103 of each unit cell 1050U. Alternatively, the base contact region 155 may be formed simultaneously with the contact region 105 of each unit cell 1050U. Further alternatively, the impurity region 174 may be formed simultaneously with the source region 104 of each unit cell 1050U.

Above the first impurity region 151 of the semiconductor layer 102, a first electrode is disposed. The first electrode is a multilayer electrode including an upper source electrode, for example. Herein, as the first electrode, a base electrode 109S, a barrier metal 112B, and a source pad 112 are stacked in this order on the semiconductor layer 102. Moreover, as shown in FIG. 22, in the case where the source line 112L is disposed outward of the source pad 112, a base electrode 109S, a barrier metal 112B, and a source line 112L are stacked in this order on the semiconductor layer 102, as the first electrode. Each base electrode 109S is in ohmic contact with the base contact region 155 of the first impurity region 151. The source pad 112 or the source line 112L is electrically connected with the first impurity region 151 via the barrier metal 112B and the base electrode 109S. The base electrode 109S mainly contains e.g. Ni. The source line 112L mainly contains e.g. Al.

The channel layer 106 and the gate insulating film 107 extend to above a portion of the first impurity region 151. Above the gate insulating film 107, the gate electrode 108 extends from each unit cell 1050U of the active region 100M. On the gate electrode 108, the barrier metal 112B and the gate line 118L are disposed in this order. The gate line 118L forms an ohmic junction with the gate electrode 108 via the barrier metal 112B. Although not shown in FIG. 22, the gate line 118L is electrically connected with the gate pad 118 shown in FIG. 20.

On the gate electrodes 108, the first insulating film 111 is disposed. The first insulating film 111 cover a portion of the first impurity region 151, and covers the plurality of rings 152. The first insulating film 111 has a plurality of first apertures 111p through which portions of the upper face of the first impurity region 151 (e.g., portions of the upper face of the base contact region 155 herein) are exposed.

Each base electrode 109S is in ohmic contact with the base contact region 155 within the first apertures 111p of the first insulating film 111. As described above, on the base electrode 109S, the barrier metal 112B and the source pad 112 or the source line 112L (as an upper source electrode) are disposed. The upper source electrode or the barrier metal 112B may cover a portion of the upper face of the first insulating film 111 and the side walls of the first apertures 111p of the first insulating film 111.

The base electrodes 109S may be simultaneously formed by using the same material as that of the aforementioned source electrode 109. In other words, they are formed by allowing Ni to react with the channel layer 106 into a silicide. Alternatively, portions of the channel layer 106 that are located in the first apertures 111p of the first insulating film 111 may be previously etched away, and Ni may be allowed to react with the semiconductor layer 102 into a silicide.

Moreover, as shown in FIG. 22, above the first impurity region 151, the first insulating film 111 has a gate aperture 111g through which a portion of each gate electrode 108 is exposed. The barrier metal 112B and the gate line 118L are disposed on a portion of the upper face of the first insulating film 111 and within the gate aperture 111g. The gate line 118L may be simultaneously formed from the same material as the source line 112L and the source pad 112.

A second insulating film 114 is disposed so as to cover a portion of the first insulating film 111. The lower end (lower face) of the second insulating film 114 is in contact with the first insulating film 111. Moreover, the second insulating film 114 is not in contact with the upper face 112S of the source pad 112 or the upper face 112LS of the source line 112L, which defines an upper face of the first electrode. The second insulating film 114 has a higher moisture resistance than that of the first insulating film 111. The second insulating film 114 contains e.g. SiN.

When viewed from the normal direction of the principal face of the semiconductor substrate 101, a portion of the second insulating film 114 overlaps the first impurity region 151 via the first insulating film 111, while another portion overlaps a portion of the FLR structure 152R via the first insulating film 111. In a region further outward of the second insulating film 114, at least one ring 152 that is not covered by the second insulating film 114 exists. When viewed from the normal direction of the principal face of the semiconductor substrate 101, the second insulating film 114 may be disposed so as to surround the active region 100M.

An inner peripheral edge 114a and an outer peripheral edge 114b of a portion of the lower face of the second insulating film 114 that is in contact with the first insulating film 111 (first face) 114S are illustrated by broken lines in FIG. 19. As has been described earlier with reference to FIG. 1, when viewed from the normal direction of the principal face of the semiconductor substrate 101, the inner peripheral edge 114a of the second insulating film 114 is disposed inward of the outer peripheral edge of the first impurity region 151. When viewed from the normal direction of the principal face of the semiconductor substrate 101, the inner peripheral edge 114a of the second insulating film 114 may be located inside the first impurity region 151. On the other hand, when viewed from the normal direction of the principal face of the semiconductor substrate 101, the outer peripheral edge 114b of the second insulating film 114 is located between a first ring 152a that is located innermost among the plurality of rings 152 and a second ring 152b that is located outermost. In other words, similarly to the aforementioned semiconductor device 1014, when viewed from the normal direction of the principal face of the semiconductor substrate 101, the first face 114S of the second insulating film 114 extends so as to cover at least the first ring 152a among the plurality of rings 152 from above a portion of the first impurity region 151. However, the extent of the first face 114S stops short of at least the second ring 152b.

Within the active region 100M and the termination region 100E, a third insulating film 115 is disposed so as to cover at least a portion of the source pad 112, at least a portion of the source line 112L, the second insulating film 114, and at least a portion of the first insulating film 111. The third insulating film 115 has an aperture 115t through which a portion of the source pad 112 is exposed. This allows an external electrical contact to be made with the source pad 112. Alternatively, above the source pad 112 being exposed through an aperture 115t in the third insulating film 115, a further metal electrode (e.g., Ni plating) may be disposed. The third insulating film 115, which is an organic insulating film, is provided in order to reduce the physical damage when sealing the semiconductor device 1050 with a resin. The third insulating film 115 may be an organic insulating film containing e.g. polyimide or polybenzoxazole.

By adopting such a configuration, a semiconductor device 1050 that is capable of switching with a high breakdown voltage and low resistance between the source pad 112 and the back face electrode 113 is realized.

As has been described with reference to FIG. 5, the semiconductor device 9010 according to Comparative Example may have a problem of cracks occurring in portions of the second insulating film 914 that are in contact with the upper face of the first electrode. On the other hand, in the semiconductor device 1050 according to the present embodiment, the second insulating film 114 is not in contact with an upper face of the first electrode mainly containing e.g. Al; that is, the second insulating film 114 is in contact with neither the upper face 112S of the source pad 112 nor the upper face 112LS of the source line 112L. Thus, the above problem is solved, whereby one of the causes for insufficiencies of the semiconductor device 1050 is eliminated.

Moreover, in the semiconductor device 1050, via the first insulating film 111, the second insulating film 114 covers the region of the semiconductor layer 102 that is located between the first impurity region 151 and the first ring 152a and at least the first ring 152a among the plurality of rings 152. As a result, even if charge or charged particles such as ions that exist in the external environment or in a sealing resin (not shown) or the third insulating film 115 is attracted toward the high-field region of the semiconductor device 1050, the second insulating film 114 restrains intrusion of charge or the charged particles into the semiconductor layer 102. A stable device operation can be realized even under the application of a high voltage, whereby not only leak fluctuations in the rated voltage can be restrained but also fluctuations in the leak current at or below the rated voltage can be suppressed.

Moreover, in the semiconductor device 1050, the distance L between the outer peripheral edge 114b of the second insulating film 114 and the outer peripheral edge of the third insulating film 115 can be set sufficiently larger than that of the semiconductor device 9010 according to Comparative Example shown in FIG. 5, for example. Specifically, the distance L may be set at 65 μm or greater. As a result, even if moisture, charge, or charged particles such as ions intruding from the side face of the first insulating film 111 or some of the portions of the surface of the first insulating film 111 that are not covered by the third insulating film 115 diffuse into the first insulating film 111, charge or the charged particles cannot arrive below the outer peripheral edge of the second insulating film 114, whereby a film lift or film delamination of the second insulating film 114 can be suppressed. Thus, not only leak fluctuations in the rated voltage can be suppressed, but also fluctuations in the leak current at or below the rated voltage can be suppressed, whereby moisture resistance can be maintained.

<Variations of MISFET>

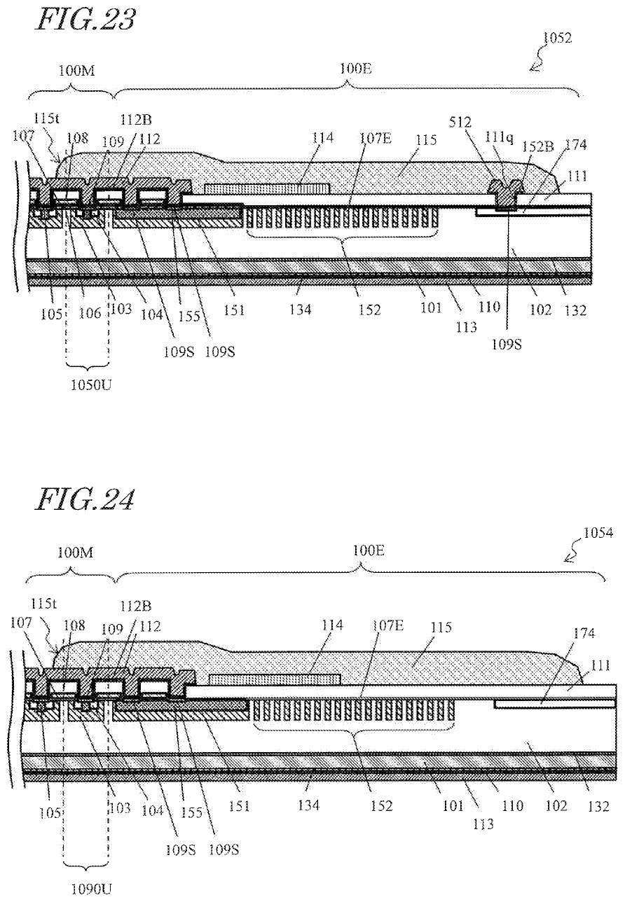

FIG. 23 and FIG. 24 are cross-sectional views respectively illustrating still other semiconductor devices (MISFETs) 1052 and 1054 according to the present embodiment, each showing a cross-sectional structure taken along line E-F in FIG. 20. Hereinafter, only the differences from the semiconductor device 1050 will be described.

The semiconductor device 1052 shown in FIG. 23 includes a seal ring 512 outside the FLR structure 152R, in order to further improve moisture resistance. When viewed from the normal direction of the principal face of the semiconductor device 1052, the seal ring 512 may be disposed so as to surround the FLR structure 152R. In this example, the first insulating film 111 has a second aperture 111q through which a portion of the impurity region 174 is exposed. Within the second aperture 111q, a base electrode 109S that is in ohmic contact with the impurity region 174 is disposed. The seal ring 512 is disposed on the base electrode 109S via the barrier metal 152B. The seal ring 512 is disposed on a portion of the upper face of the first insulating film 111 and in the second aperture 111q, extending through the first insulating film 111 along the thickness direction. This allows moisture intruding from the region at the outer periphery side of the seal ring 512 to be blocked more effectively, thereby enabling a further improvement in the moisture resistance of the semiconductor device.

The semiconductor device 1054 shown in FIG. 24 differs from the aforementioned semiconductor device 1050 in that it lacks a channel layer. In the semiconductor device 1054, each unit cell 1052U lacks the channel layer; therefore, in order to appropriately adjust the threshold voltage when the semiconductor device 1054 is to function as a MISFET, the p type impurity concentration in the body regions 103 is made lower than the impurity concentration in the body regions 103 of the semiconductor device 1050. Even without forming the channel layer, adopting the device structure according to the present disclosure can realize a semiconductor device having a high breakdown voltage and a high reliability.

Although the aforementioned semiconductor devices 1050, 1052 and 1054 are MISFETs, a semiconductor device according to an embodiment of the present disclosure may be an insulated gate bipolar transistor (IGBT) in which a semiconductor substrate 101 of a different conductivity type from that of the semiconductor layer 102 is used.

Although the above embodiments illustrate examples where the silicon carbide is 4H—SiC, the silicon carbide may be of other polytypes, e.g., 6H—SiC, 3C—SiC, or 15R—SiC. Although embodiments of the present disclosure illustrate examples where the principal face of the SiC substrate is a face that is off-cut from the (0001) face, the principal face of the SiC substrate may be the (11-20) face, the (1-100) face, the (000-1) face, or any off-cut face therefrom. Moreover, an Si substrate may be used as the semiconductor substrate 101. A 3C—SiC drift layer may be formed on the Si substrate. In this case, an annealing for activating the impurity ions implanted into the 3C—SiC may be performed at a temperature that is equal to or below the melting point of the Si substrate.

The present disclosure is applicable to power semiconductor devices to be mounted on power converters for consumer-use, onboard-use or for use in industrial equipment, for example.

This application is based on Japanese Patent Applications No. 2020-009029 filed on Jan. 23, 2020, the entire contents of which are hereby incorporated by reference.

What is claimed is:

1. A semiconductor device comprising:
a semiconductor substrate including an active region and a termination region that surrounds the active region, the semiconductor substrate having a principal face and a rear face;
a silicon carbide semiconductor layer of a first conductivity type disposed on the principal face of the semiconductor substrate, the semiconductor layer;
a first impurity region of a second conductivity type located on a surface of the semiconductor layer within the termination region, the first impurity region surrounding the active region when viewed from a normal direction of the principal face of the semiconductor substrate;
a plurality of rings of the second conductivity type located on the surface of the semiconductor layer within the termination region, the plurality of rings being spaced apart from the first impurity region and surrounding the first impurity region when viewed from the normal direction of the principal face of the semiconductor substrate;
a first insulating film disposed on the semiconductor layer so as to cover a portion of the first impurity region and the plurality of rings, the first insulating film having a first aperture above the portion of the first impurity region;
a first electrode disposed on the first insulating film and within the first aperture, the first electrode being electrically connected to the first impurity region;
a second insulating film disposed on the first insulating film within the termination region so as to surround the active region, the second insulating film having a higher moisture resistance than that of the first insulating film;
a third insulating film being located above the first insulating film and covering a portion of the first electrode and the second insulating film within the active region and the termination region, the third insulating film being an organic insulating film; and
a second electrode disposed on the rear face of the semiconductor substrate, wherein,
the second insulating film has a first face that is in contact with the first insulating film, and, when viewed from the normal direction of the principal face of the semiconductor substrate,
the first face surrounds the active region,
an inner peripheral edge of the first face is located inward of an outer peripheral edge of the first impurity region, and
an outer peripheral edge of the first face is located between a first ring and a second ring among the plurality of rings, the first ring being located innermost and the second ring being located outermost among the plurality of rings; and
the second insulating film is not in contact with an upper face of the first electrode.

2. The semiconductor device of claim 1, wherein the second insulating film comprises silicon nitride.

3. The semiconductor device of claim 1, wherein,
when viewed from the normal direction of the principal face of the semiconductor substrate, an outer peripheral edge of the third insulating film is located outward of the outer peripheral edge of the first face of the second insulating film; and
in a plane parallel to the principal face of the semiconductor substrate, a minimum distance L between the outer peripheral edge of the first face of the second insulating film and the outer peripheral edge of the third insulating film satisfies L≥65 μm.

4. The semiconductor device of claim 1, wherein the second insulating film is not in contact with the first electrode.

5. The semiconductor device of claim 1, wherein the first insulating film is a silicon oxide film.

6. The semiconductor device of claim 1, wherein,
the first insulating film has a second aperture through which a portion of the semiconductor layer is exposed, and, when viewed from the normal direction of the principal face of the semiconductor substrate, the second aperture is located outward of the plurality of rings,
the semiconductor device further comprising a seal ring disposed on the first insulating film and within the second aperture.

7. The semiconductor device of claim 6, wherein the third insulating film covers the seal ring.

8. The semiconductor device of claim 1, wherein the first electrode has a multilayer structure, the multilayer structure including as a lowermost layer a metal layer that is in contact with the semiconductor layer, the metal layer forming a Schottky junction with the semiconductor layer.

9. The semiconductor device of claim 8, comprising within the active region a plurality of barrier regions of the second conductivity type that are located on the surface of the semiconductor layer.

10. The semiconductor device of claim 1, further comprising a plurality of unit cells disposed in the active region,
each of the plurality of unit cells comprising:
a body region of the second conductivity type selectively formed on the surface of the semiconductor layer;
a source region of the first conductivity type located on a surface of the body region and being disposed at a distance from an outer peripheral edge of the body region;
a contact region of the second conductivity type selectively formed on the surface of the semiconductor layer, the contact region containing an impurity of the second conductivity type at a higher concentration than that in the body region, the contact region adjoining the source region and being connected to the body region;
a gate insulating film disposed on the semiconductor layer;
a gate electrode being located on the gate insulating film and covering a portion of the body region via the gate insulating film; and
a source electrode forming ohmic junctions with the source region and the contact region;
the first insulating film covers an upper face and a side face of the gate electrode; and
the first electrode is electrically connected with the source electrode.
